(19) United States
(12) Patent Application Publication
(10) Pub. No.: US 2016/0054651 A1
(43) Pub. Date: Feb. 25, 2016

(54) PHOTOSENSITIVE RESIN COMPOSITION FOR BLACK MATRIX AND APPLICATION THEREOF

(71) Applicant: CHI MEI CORPORATION, Tainan City (TW)

(72) Inventors: Chun-An Shih, TAINAN CITY (TW); Hao-Wei Liao, KAOHSIUNG CITY (TW); Li-Ting Hsieh, TAINAN CITY (TW); Chen-Yu Wu, Taipei City (TW)

(21) Appl. No.: 14/934,013

(22) Filed: Nov. 5, 2015

Related U.S. Application Data
(63) Continuation-in-part of application No. 14/614,377, filed on Feb. 4, 2015.

(30) Foreign Application Priority Data
Feb. 13, 2014 (TW) 103104745
Nov. 25, 2014 (TW) 103140844

(51) Int. Cl. G03F 7/033; G02B 5/00; G02F 1/1335; G02B 1/04

(52) U.S. Cl. CPC G03F 7/033; G02B 1/04; G02B 5/003; G02F 1/133512

(57) ABSTRACT

The present invention relates to a photosensitive resin composition for a black matrix and an application thereof. The aforementioned photosensitive resin composition includes an alkali-soluble resin (A), a compound having an ethylenically unsaturated group (B), a photo-initiator (C), a solvent (D), a black pigment (E) and an oxetane compound having silicon atom (F). The aforementioned alkali-soluble resin (A) includes a first alkali-soluble resin (A-1) having a fluorine atom. The photosensitive resin composition for the black matrix has excellent development resistance and lower surface resistance.

### RELATED APPLICATIONS

This application claims priority to Taiwan Application Serial Number 103140844, filed on Nov. 25, 2014, which is herein incorporated by reference.

### BACKGROUND

1. Field of Invention

The present invention relates to photosensitive resin composition for a black matrix and an application thereof. More particularly, the present invention relates a photosensitive resin composition that has excellent development resistance and lower surface resistance, a color filter formed by the photosensitive resin composition, and a liquid crystal display device including the color filter.

2. Description of Related Art

Recently, with various technologies of liquid crystal display are promptly developed, a black matrix is generally configured in gaps between stripes and dots of a color filter in a liquid crystal display, for improving contrast ratio and display quality of the liquid crystal display. The aforementioned black matrix can prevent reductions of the contrast ratio and the color purity due to light leakage between pixels.

Generally, the black matrix can be a deposited film including chromium, chromium oxide or the like. However, when the black matrix is manufactured by the aforementioned deposited film, the process has the defects of complicated processes, expensive material and the like. The black matrix is formed by photo lithographic to solve the issue.

Nevertheless, in the process for producing the color filter, there is a larger level difference between the black matrix and end parts of color pixels (i.e. red, green and blue pixels), thereby inducing a defect of non-uniform color displaying. For overcoming the defect, Japan Parent Laid Open No. 1993-074483 discloses a photosensitive resin composition with high cross-linking density, and Japan Patent Laid Open No. 1998-133372 discloses a composition having epoxy compounds for a protective film, so as to improve the aforementioned defect of level difference. The photosensitive resin compositions have defects of poor development resistance and surface resistance though the level difference is solved.

Moreover, Japan Patent Laid Open No. 1993-070528 discloses an alkali-soluble resin obtained by reacting with an epoxy acrylate compound having a fluorene ring and an anhydride compound. However, the alkali-soluble resin has defects of poor development resistance and surface resistance, too.

Accordingly, there is a need to provide a photosensitive resin composition for a black matrix with excellent development resistance and surface resistance, thereby overcoming the aforementioned defects of the conventional black matrix.

### SUMMARY

Therefore, an aspect of the present invention provides a photosensitive resin composition for a black matrix. The photosensitive resin composition has excellent development resistance and lower surface resistance.

Another aspect of the present invention provides a black matrix. The black matrix is formed by the aforementioned photosensitive resin composition.

A further aspect of the present invention provides a liquid crystal display device. The liquid crystal display device includes the aforementioned black matrix.

According to the aforementioned aspect, the present invention provided the photosensitive resin composition for the black matrix. The photosensitive resin composition includes an alkali-soluble resin (A), a compound having an ethylenically unsaturated group (B), a photo-initiator (C), a solvent (D), a black pigment (E) and an oxetane compound having silicon atom (F) all of which are described in details as follows.

### Alkali-Soluble Resin (A)

The alkali-soluble resin (A) of the present invention includes a first alkali-soluble resin (A-1). Moreover, the alkali-soluble resin (A) can selectively include a second alkali-soluble resin (A-2) and an other alkali-soluble resin (A-3).

### First Alkali-Soluble Resin (A-1)

The first alkali-soluble resin (A-1) can optionally be a compound having a structure of Formula (I):

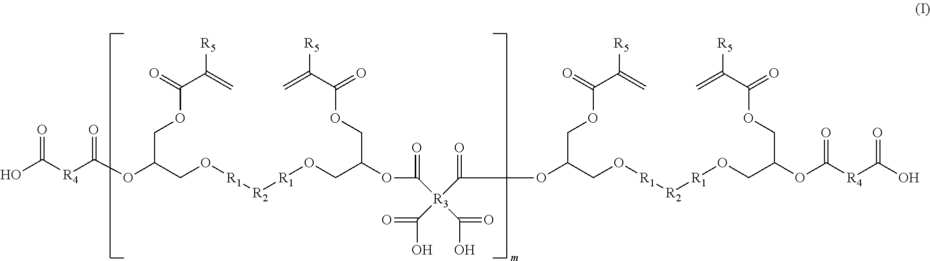

in the Formula (I), R₁ represents a phenylene group or a phenylene having a substituted group, wherein the substituted group can optionally be an alkyl group of 1 to 5 carbons, a halogen atom or a phenyl group; R₂ represents —CO—, —SO₂—, —C(CF₃)₂—, —SI(CH₃)₂—, —CH₂—, —C(CH₃)₂—, —O—, 9,9-fluorenylidene or a single bond; R₃ represents a tetravalent carboxylic residual group; R₄ represents a divalent carboxylic residual group, wherein at least one of R₃ and R₄ have a fluorine atom; R₅ represents a hydrogen atom or a methyl group; and m represents an integer of 1 to 20.

R₃ can be the tetravalent carboxylic residual group having a fluorine atom or the tetravalent carboxylic residual group without a fluorine atom, preferably be the tetravalent carboxylic residual group having a fluorine atom, and more preferably be benzene having a fluorine atom.

The alkali-soluble resin (A-1) can be obtained by reacting with a first mixture. The first mixture includes a glycol compound having a polymeric unsaturated group (a-1), a tetracarboxylic acid or a dianhydride compound thereof (a-2) and a dicarboxylic acid or an anhydride compound thereof (a-3). At least one of a tetracarboxylic acid or a dianhydride compound thereof (a-2) and a dicarboxylic acid or an anhydride compound thereof (a-3) has a fluorine atom.

Glycol Compound Having a Polymeric Unsaturated Group (a-1)

The glycol compound having a polymeric unsaturated group (a-1) is obtained by reacting with bisphenol compound having two epoxy groups (a-1-1) and a compound having at least one carboxylic group and at least one ethylenically unsaturated group (a-1-2). The reactant for synthesizing the glycol compound having a polymeric unsaturated group (a-1) can include other compounds.

The bisphenol compound having two epoxy groups (a-1-1) can be obtained by performing dehydrohalogenation to a bisphenol compound and epihalohydrin under the existence of an alkali metal hydroxide.

Examples of the bisphenol compound for synthesizing the bisphenol compound having two epoxy groups (a-1-1) can include but be not limited to bis(4-hydroxyphnenyl)ketone, bis(4-hydroxy-3,5-dimethylphnenyl)ketone, bis(4-hydroxy-3,5-dichlorophnenyl)ketone, bis(4-hydroxyphnenyl)ketone, bis(4-hydroxyphnenyl)sulfone, bis(4-hydroxy-3,5-dimethylphnenyl)sulfone, bis(4-hydroxy-3,5-dichlorophnenyl)sulfone, bis(4-hydroxyphenyl)hexafluoro propane, bis(4-hydroxy-3,5-dimethylphenyl)hexafluoropropane, bis(4-hydroxy-3,5-dichlorophenyl)hexafluoropropane, bis(4-hydroxyphenyl)dimethylsilane, bis(4-hydroxy-3,5-dimethylphenyl)dimethylsilane, bis(4-hydroxy-3,5-dichloro phenyl)dimethylsilane, bis(4-hydroxyphenyl)methane, bis(4-hydroxy-3,5-dichlorophenyl)methane, bis(4-hydroxy-3,5-dibromophenyl)methane, 2,2-bis(4-hydroxyphenyl)propane, 2,2-bis(4-hydroxy-3,5-dimethylphenyl) propane, 2,2-bis(4-hydroxy-3,5-dichlorophenyl)propane, 2,2-bis(4-hydroxy-3-methylphenyl)propane, 2,2-bis(4-hydroxy-3-chlorophenyl)propane, bis(4-hydroxyphenyl)ether, bis(4-hydroxy-3,5-dimethylphenyl)ether, bis(4-hydroxy-3,5-dichlorophenyl)ether, 9,9-bis(4-hydroxyphenyl)fluorine, 9,9-bis(4-hydroxy-3-dimethylphenyl)fluorine, 9,9-bis(4-hydroxy-3-chlorophenyl)fluorine, 9,9-bis(4-hydroxy-3-bromophenyl)fluorine, 9,9-bis(4-hydroxy-3-fluorophenyl) fluorine, 9,9-bis(4-hydroxy-3,5-dimethylphenyl)fluorine, or a combination thereof.

Examples of the aforementioned epihalohydrin for synthesizing the bisphenol compound having two epoxy groups (a-1-1) can include but be not limited to epichlorohydrin, epibromohydrin or a combination thereof. Based on a total equivalent of the hydroxy group in the aforementioned bisphenol compound as 1 equivalent, an amount of the epihalohydrin can be 1 equivalent to 20 equivalent, and preferably is 2 equivalents to 10 equivalents.

Examples of the alkali metal hydroxide can include sodium hydroxide, potassium hydroxide or a combination thereof. Based on a total equivalent of the hydroxy group in the aforementioned bisphenol compound as 1 equivalent, an amount of the alkali metal hydroxide in the dehydrohalogenation can be 0.8 equivalents to 15 equivalents, and preferably is 0.9 equivalents to 11 equivalents.

Before the dehydrohalogenation is performed, the alkali metal hydroxide such as sodium hydroxide, potassium hydroxide or the like can be pre-added or added during the reaction. The reaction temperature of the dehydrohalogenation is 20° C. to 120° C. and the reaction time thereof is 1 hour to 10 hours.

In an embodiment, the aforementioned alkali metal hydroxide added in the dehydrohalogenation can also be an aqueous solution. In the embodiment, when the aqueous solution of alkali metal hydroxide is continuously added in the dehydrohalogenation system, water and epihalohydrin can be continuously distilled under reduced pressure or normal pressure, thereby separating and removing water, such that epihalohydrin can be continuously flown back to the system.

Before the dehydrohalogenation is performed, a quaternary ammonium salt, such as tetramethyl ammonium chloride, tetramethyl ammonium bromide, trimethyl benzyl ammonium chloride or the like, can be added as a catalyst. The alkali metal hydroxide or the aqueous solution thereof is added after reacting at 50° C. to 150° C. for 1 hour to 5 hours. Then, the mixture is reacted at 20° C. to 120° C. for 1 hour to 10 hours to performing the dehydrohalogenation.

Besides, for performing the dehydrohalogenation smoothly, except an alcohol such as methanol, ethanol or the like can be added to the reaction system, an aprotic polar solvent such as dimethyl sulfone, dimethyl sulfoxide or the like can also be added to perform the reaction. When the alcohols are added, based on a total amount of the epihalohydrin as 100 weight percentage (wt %), an amount of the alcohols can be 2 wt % to 20 wt %, and preferably is 4 wt % to 15 wt %. When the aprotic polar solvent is added, based on the total amount of the epihalohydrin as 100 wt %, an amount of the aprotic polar solvent is 5 wt % to 100 wt %, and preferably is 10 wt % to 90 wt %.

To prevent the epoxy resin formed from containing a hydrolyzable halogen, the solution after the dehydrohalogenation can be added to a solvent such as benzene, toluene, methyl isobutyl ketone or the like, and an aqueous alkali metal hydroxide solution such as sodium hydroxide, potassium hydroxide or the like for performing the dehydrohalogenation again. In the dehydrohalogenation, based on a total equivalent of the hydroxyl group in the aforementioned bisphenol compound as 1 equivalent, an amount of the alkali metal hydroxide is 0.01 moles to 1 mole, and preferably is 0.05 moles to 0.9 moles. Moreover, the reaction temperature of the dehydrohalogenation is 50° C. to 120° C. and the reaction time thereof is 0.5 hours to 2 hours.

After the dehydrohalogenation is completed, salts can be removed by processes, such as filtering, rinsing and the like. Besides, the solvents, such as benzene, toluene, methyl isobutyl ketone and the like can be distilled by distillation under reduced pressure, thereby obtaining the bisphenol compound having two epoxy groups (a-1-1).

The bisphenol compound having two epoxy groups (a-1-1) preferably can be a bisphenol compound having two epoxy groups shown as Formula (I-11) or a polymer polymerized by a bisphenol compound having two epoxy groups shown as Formula (I-12):

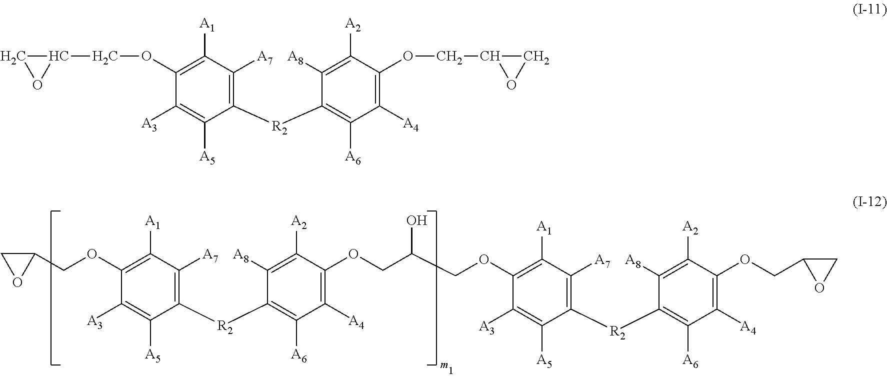

in Formula (I-11) and (I-12), A₁ to A₈ respectively represents a hydrogen atom, a halogen atom, an alkyl group of 1 to 5 carbons or a phenyl group, R₂ represents —CO—, —SO₂—, —C(CF₃)₂—, —Si(CH₃)₂—, —CH₂—, —C(CH₃)₂—, —O—, 9,9-fluorene or a single bond. m₁ can represent an integer of 1 to 10, and preferably is 1 to 2.

The bisphenol compound having two epoxy groups shown as Formula (I-11) preferably can be a bisphenol compound having two epoxy groups shown as Formula (I-13):

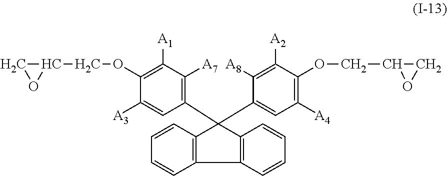

in Formula (I-13), A₁, A₂, A₃, A₄, A₇ and A₈ respectively represents a hydrogen atom, a halogen atom, an alkyl group of 1 to 5 carbons or a phenyl group.

The bisphenol compound having two epoxy groups shown as Formula (I-13) can be obtained by reacting with bisphenol fluorine and epihalohydrin.

Examples of the aforementioned bisphenol fluorene can include 9,9-bis(4-hydroxyphenyl)fluorene, 9,9-bis(4-hydroxy-3-methylphenyl)fluorene, 9,9-bis(4-hydroxy-3-chlorophenyl)fluorene, 9,9-bis(4-hydroxy-3-bromophenyl) fluorene, 9,9-bis(4-hydroxy-3-fluorophenyl)fluorene, 9,9-bis(4-hydroxy-3-methoxyphenyl)fluorene, 9,9-bis(4-hydroxy-3,5-dimethylphenyl)fluorene, 9,9-bis(4-hydroxy-3,5-dichlorophenyl)fluorene, 9,9-bis(4-hydroxy-3,5-dibromo phenyl)fluorene or a combination thereof.

Examples of the epihalohydrin can include epichlorohydrin, epibromohydrin or a combination thereof.

Examples of the bisphenol fluorene compound can include but be not limited to (a) products made by Nippon Steel Co., Ltd., and the trade name is ESF-300 or the like; (2) products made by Osaka Gas Co., Ltd., and the trade name is PG-100, EG-210 or the like; or (3) products made by S.M.S Technology Co., Ltd., and the trade name is SMS-F9PhPG, SMS-F9CrG, SMS-F914PG or the like.

The compound having at least one carboxylic group and at least one ethylenically unsaturated group (a-1-2) can include but be not limited to acrylate, methacrylate, 2-methacryloyloxyethylbutanedioic acid, 2-methacryloyloxybutylbutanedioic acid, 2-methacryloyloxyethylhexanedioic acid, 2-methacryloyloxybutylhexanedioic acid, 2-methacryloyloxyethylhexahydrophthalic acid, 2-methacryloyloxyethylmaleic acid, 2-methacryloyloxypropylmaleic acid, 2-methacryloyloxybutylmaleic acid, 2-methacryloyloxypropylbutanedioic acid, 2-methacryloyloxypropylhexanedioic acid, 2-methacryloyloxypropyltetrahydrophthalic acid, 2-methacryloyloxypropylphthalic acid, 2-methacryloyloxybutylphthalic acid, 2-methacryloyloxybutylhydrophthalic acid; a compound obtained by reacting (meth)acrylate having a hydroxyl group and a dicarboxylic acid, and examples of the dicarboxylic acid can include but be not limited to hexanedioic acid, butanedioic acid, maleic acid, phthalic acid or the like; a half ester compound obtained by reacting (meth)acrylate having a hydroxyl group and a carboxylic anhydride, and examples of the (meth)acrylate having a hydroxyl group can include but be not limited to (2-hydroxyethyl)acrylate, (2-hydroxyethyl)methacrylate, (2-hydroxypropyl)acrylate, (2-hydroxypropyl) methacrylate, (4-hydroxybutyl)acrylate, (4-hydroxybutyl)methacrylate, pentaerythritol trimethacrylate or the like. Besides, the examples of the carboxylic anhydride can be the same as examples of a tetracarboxylic dianhydride compound of a following other tetracarboxylic acid or a dianhydride compound thereof (a-2-2) and examples of a dicarboxylic anhydride compound of a following other dicarboxylic acid or an anhydride compound (a-3-2) rather than focusing or mentioned them in details.

Tetracarboxylic Acid or Dianhydride Compound Thereof (a-2)

A tetracarboxylic acid or a dianhydride compound thereof (a-2) can include a tetracarboxylic acid having a fluorine atom or a dianhydride compound thereof (a-2-1), and an other tetracarboxylic acid or a dianhydride compound thereof (a-2-2) besides a tetracarboxylic acid having a fluorine atom or a dianhydride compound thereof (a-2-1).

The aforementioned tetracarboxylic acid having a fluorine atom or a dianhydride compound thereof can include but be not limited to a tetracarboxylic acid having a fluorine atom having a structure of Formula (I-1), a tetracarboxylic dianhydride compound having a fluorine atom having a structure of Formula (I-2) and a combination thereof:

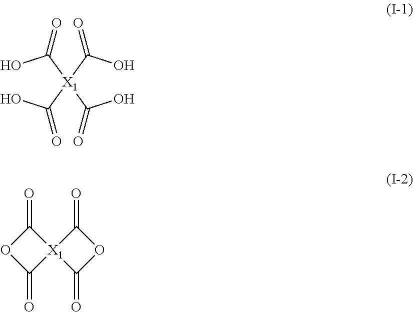

in the Formula (I-1) and (I-2), X₁ represents a group having a structure of Formula (I-3) to (I-8):

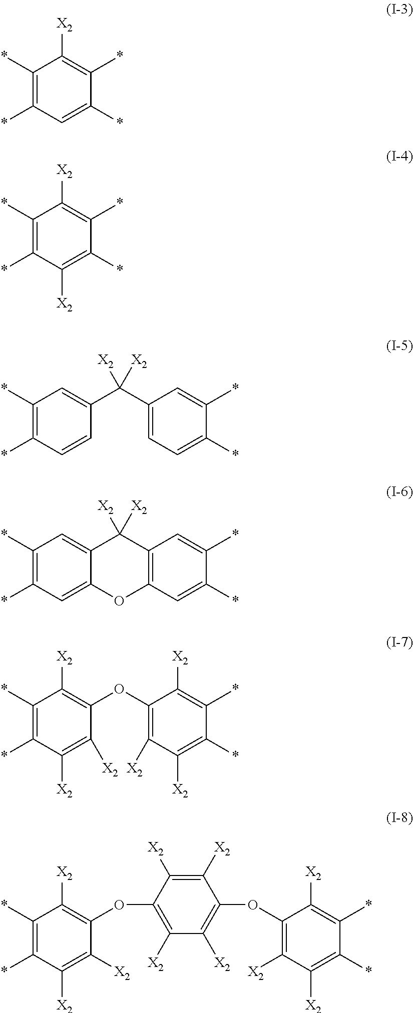

in the Formula (I-3) to (I-8), X₂ respectively represents a fluorine atom or a trifluoromethyl, and “*” represents a position bonding with a carbon atom.

For example, a tetracarboxylic acid having a fluorine atom or a dianhydride compound thereof (a-2-1) can include but be not limited to aromatic tetracarboxylic acid, such as 4,4′-hexafluoro isopropylidene diphthalic acid, 1,4-difluoropyromellitic acid, 1-monofluoropyromellitic acid, 1,4-ditrifluoromethylpyromellitic acid or the like, dianhydride compounds of the aforementioned tetracarboxylic acid, or a combination thereof.

The examples of a tetracarboxylic acid having a fluorine atom or a dianhydride compound thereof (a-2-1) can include tetracarboxylic acids having a fluorine atom, such as 3,3′-(hexafluoro isopropylidene)diphthalic acid, 5,5′-{2,2,2-trifluoro-1-[3-(trifluoromethyl)phenyl]ethylidene}diphthalic acid, 5,5′-[2,2,3,3,3-pentafluoro-1-(trifluoromethyl)propylidene]diphthalic acid, 5,5′-oxybis(4,6,7-trifluoro-pyromellitic acid), 3,6-bis(trifluoromethyl)pyromellitic acid, 4-(trifluoromethyl) pyromellitic acid 1,4-bis(3,4-dicarboxylic acid trifluorophenoxy)tetrafluoro benzene or the like, dianhydride compounds of the aforementioned tetracarboxylic acids, or a combination thereof.

The aforementioned other tetracarboxylic acid or a dianhydride compound thereof (a-2-2) can include saturated linear hydrocarbon tetracarboxylic acid, alicyclic tetracarboxylic acid, aromatic tetracarboxylic acid, dianhydride acid s thereof, or a combination thereof.

For example, the saturated linear hydrocarbon tetracarboxylic acid can include butane tetracarboxylic acid, pentane tetracarboxylic acid, hexane tetracarboxylic acid or a combination thereof. The saturated linear hydrocarbon tetracarboxylic acid can have a substituted group.

For examples, the alicyclic tetracarboxylic acid can include cyclobutane tetracarboxylic acid, cyclopentane tetracarboxylic acid, cyclohexane tetracarboxylic acid, norbornane tetracarboxylic acid or a combination thereof. The alicyclic tetracarboxylic acid can have a substituted group.

For examples, the aromatic tetracarboxylic acid can include pyromellitic acid, benzophenone tetracarboxylic acid, biphenyl tetracarboxylic acid, oxydiphthalic tetracarboxylic acid, diphenyl sulfonete tracarboxylic acid, 1,2,3,6-Tetrahydrophthalic acid or a combination thereof. The aromatic tetracarboxylic acid can have a substituted group.

Dicarboxylic Acid or Anhydride Compound Thereof (a-3)

A dicarboxylic acid or an anhydride compound thereof (a-3) can include a dicarboxylic acid having a fluorine atom or an anhydride compound thereof (a-3-1) and an other dicarboxylic acid having a fluorine atom or an anhydride compound thereof (a-3-2) beside a dicarboxylic acid having a fluorine atom or an anhydride compound thereof (a-3-1).

A dicarboxylic acid having a fluorine atom or an anhydride compound thereof (a-3-1) can include but be not limited to a dicarboxylic acid having a fluorine atom shown as Formula (I-9), a dicarboxylic anhydride compound having a fluorine atom shown as Formula (I-10) or a combination thereof:

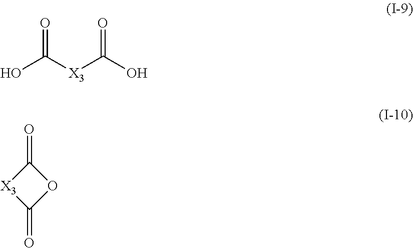

in Formula (I-9) and (I-10), X₃ can represent an organic group having a fluorine atom of 1 to 100 carbons.

For example, a dicarboxylic acid or an anhydride compound thereof (a-3-1) can include 3-fluorophthalic acid, 4-fluorophthalic acid, tetrafluorophthalic acid, 3,6-difluorophthalic acid, tetrafluoro succinic acid, anhydride compounds of the aforementioned dicarboxylic acid or a combination thereof.

Examples of an other dicarboxylic acid or an anhydride compound thereof (a-3-2) can include saturated linear hydrocarbon dicarboxylic acid, saturated cyclohydrocarbon, unsaturated dicarboxylic acid, anhydride compounds of the aforementioned dicarboxylic acid or a combination thereof.

Examples of the saturated linear hydrocarbon dicarboxylic acid can include succinic acid, acetyl succinic acid, adipic acid, azelaic acid, citramalic acid, malonic acid, glutaric acid, citric acid, tartaric acid, oxoglutaric acid, pimelic acid, sebacic acid, suberic acid, diglycolic acid or a combination thereof. The hydrocarbon group in the saturated linear hydrocarbon dicarboxylic acid can be substituted.

Examples of the saturated cyclohydrocarbon can include hexahydroxyl phthalic acid, cyclobutane dicarboxylic acid, cyclopentane dicarboxylic acid, norbornane dicarboxylic acid, hexahydrotrimellitic acid or a combination thereof. The saturated cyclohydrocarbon dicarboxylic acid can be alicyclic dicarboxylic acid substituted by saturated hydrocarbon group.

Examples of the unsaturated dicarboxylic acid can include maleic acid, itaconic acid, o-phthalic acid, tetrahydro phthalic acid, methyl endo-methylene tetrahydro phthalic acid, chlorendic acid, trimellitic acid or a combination thereof.

For examples, an other dicarboxylic acid or an anhydride compound thereof (a-3-2) can include trimethoxysilylpropyl succinic anhydride, triethoxysilylpropyl succinic anhydride, methyldimethoxysilylpropyl succinic anhydride, methyldiethoxysilylpropyl succinic anhydride, trimethoxysilylbutyl succinic anhydride, triethoxysilylbutyl succinic anhydride, methyldiethoxysilylbutyl succinic anhydride, p-(trimethoxysilyl)phenyl succinic anhydride, p-(triethoxysilyl)phenyl succinic anhydride, p-(methyldimethoxysilyl)phenyl succinic anhydride, p-(methyldiethoxysilyl)phenyl succinic anhydride, m-(trimethoxysilyl)phenyl succinic anhydride, m-(triethoxysilyl)phenyl succinic anhydride, m-(methyldiethoxysilyl)phenyl succinic anhydride, dicarboxylic acid of the aforementioned dicarboxylic anhydride compound or a combination thereof.

The dicarboxylic acid preferably can be succinic acid, itaconic acid, tetrahydro phthalic acid, hexahydro phthalic acid, o-phthalic acid, trimellitic acid or a combination thereof, and preferably can be succinic acid, itaconic acid, tetrahydro phthalic acid or a combination thereof.

The dicarboxylic anhydride preferably can be succinic anhydride, itaconic anhydride, tetrahydro phthalic anhydride, hexahydro phthalic anhydride, o-phthalic anhydride, trimellitic anhydride or a combination thereof.

There is no particular limitation for the synthesized method of the alkali-soluble resin (A-1), and the alkali-soluble resin (A-1) can be obtained by reacting with the glycol compound having a polymeric unsaturated group (a-1), a tetracarboxylic acid or a dianhydride compound thereof (a-2) and a dicarboxylic acid or an anhydride compound thereof (a-3).

When the aforementioned alkali-soluble resin (A-1) is produced, an alkali compound is added into the reacting solution as a catalyst for accelerating the reaction. Examples of the catalyst can include triphenyl phosphine, triphenyl stibine, triethylamine, triethanolamine, tetramethylammonium chloride, benzyltriethylammonium chloride or a combination thereof. The catalyst can be used alone or in a combination of two or more.

Moreover, in order to control the polymerized degree, an inhibitor is added into the reacting solution. Examples of the inhibitor can include methoxyphenol, methylhydroquinone, hydroquinone, 2,6-di-tert-butyl-p-cresol, phenothiazine or the like. The aforementioned inhibitor can be used alone or in a combination of two or more.

When the alkali-soluble resin (A-1) is produced, if necessarily, a polymerized reacting solvent can be used. Examples of the polymerized reacting solvent can include but be not limited to alcohol compound, such as ethanol, propanol, isoproponal, butanol, isobutanol, 2-butanol, hexanol, ethylene glycol or the like; ketone compound, such as methyl ethyl ketone, cyclohexanone or the like; aromatic hydrocarbon compound, such as toluene, xylene or the like; cellosolve compound, such as cellosolve, butyl cellosolve or the like; carbitol compounds, such as carbitol, butyl carbitol or the like; propylene glycol alkyl ether compounds, such as propylene glycol monomethyl ether or the like; poly(propylene glycol) alkyl ether compounds, such as di(propylene glycol)methyl ether or the like; acetate ester compounds, such as ethyl acetate, butyl acetate, ethylene glycol monoethyl ether acetate, propylene glycol methyl ether acetate or the like; alkyl lactate compounds, such as ethyl lactate, butyl lactate or the like; dialkyl glycol ether compounds; or other ester compounds, such as 2-hydro-2-methylmethyl propionate, 2-hydro-2-methylethyl propionate, 3-methoxymethyl propionate, 3-methoxyethyl propionate, 3-ethoxymethyl propionate, 3-ethoxyethyl propionate (EEP), ethoxyethylacetate or the like. The aforementioned polymerized reacting solvent can be used alone or in a combination of two or more. An acid value of the alkali-soluble resin (A-1) is 50 mgKOH/g to 200 mgKOH/g, and preferably is 60 mgKOH/g to 180 mgKOH/g.

Besides, the synthesized method of the alkali-soluble resin (A-1) can be a method disclosed in Japan Patent Laid Open No. 1997-325494. the synthesized method can be a conventional method where diol compound and tetracarboxylic dianhydride are reacted at 90° C. to 140° C. At 90° C. to 130° C., the first mixture is uniformly dissolved to react. Then, the mixture reacts and aging at 40° C. to 80° C.

The first alkali-soluble resin (A-1) obtained by the first mixture reaction is an alkali-soluble resin having a fluorine atom, and preferably is an alkali-soluble resin having an aromatic structure with a fluorine atom.

In the compositions of the first mixture for forming the first alkali-soluble resin, at least one of a tetracarboxylic acid or a dianhydride compound thereof (a-2) and a dicarboxylic acid or an anhydride compound thereof (a-3) have a fluorine atom, and preferably both a tetracarboxylic acid or a dianhydride compound thereof (a-2) and a dicarboxylic acid or an anhydride compound thereof (a-3) have a fluorine atom.

In detail, when a tetracarboxylic acid or a dianhydride compound thereof (a-2) has a fluorine atom, a tetracarboxylic acid or a dianhydride compound thereof (a-2) can include a tetracarboxylic acid having a fluorine atom or a dianhydride compound thereof (a-2-1); when a dicarboxylic acid or an anhydride compound thereof (a-3) has a fluorine atom, a dicarboxylic acid or an anhydride compound thereof (a-3) can include a dicarboxylic acid having a fluorine atom or an anhydride compound thereof (a-3-1).

Neither a tetracarboxylic acid or a dianhydride compound thereof (a-2) nor a dicarboxylic acid or an anhydride compound thereof (a-3) has a fluorine atom, the photosensitive resin composition has poor development resistance.

Based on a total amount of the alkali-soluble resin (A) as 100 parts by weight, an amount of the first alkali-soluble resin (A-1) is 10 parts by weight to 100 parts by weight, preferably is 12 parts by weight to 95 parts by weight, and more preferably is 15 parts by weight to 90 parts by weight.

The first alkali-soluble resin (A-1) has water repellency, thereby enhancing the development resistance of the photosensitive resin composition. Moreover, a Van der Waals force between the first alkali-soluble resin (A-1) and the following black pigment (E) is stronger, thereby providing better protection to the black pigment (E), further enhancing the surface resistance of the photosensitive resin composition.

When the alkali-soluble resin (A) does not include the first alkali-soluble resin (A-1), the photosensitive resin composition has defects of poor development resistance and surface resistance.

Beside, when a mole number of the glycol compound having a polymeric unsaturated group (a-1), a mole number of a tetracarboxylic acid having a fluorine atom or a dianhydride compound thereof (a-2-1) and a mole number of a dicarboxylic acid having a fluorine atom or an anhydride compound thereof (a-3-1) can satisfy a formula of [(a-2-1)+(a-3-1)]/(a-1)=0.4 to 1.6, the photosensitive resin composition can further enhance the development resistance of the photosensitive resin composition.

### Second Alkali-Soluble Resin (A-2)

The alkali-soluble resin (A) can selectively include the second alkali-soluble resin (A-2). The second alkali-soluble resin (A-2) has a structure of Formula (V):

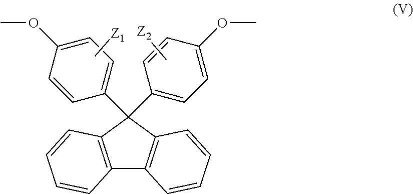

in the Formula (V), Z₁ and Z₂ respectively represents a hydrogen atom, a linear alkyl group of 1 to 5 carbons, a branched alkyl group of 3 to 5 carbons, a phenyl group or a halogen atom.

The second alkali-soluble resin (A-2) is obtained by reacting with the compound having a structure of Formula (V) and an other copolymerizable compound. The compound having a structure of Formula (V) can be bisphenol fluorene compound having two epoxy groups shown as Formula (V-1) or bisphenol fluorene compound having two hydroxyl groups shown as Formula (V-2):

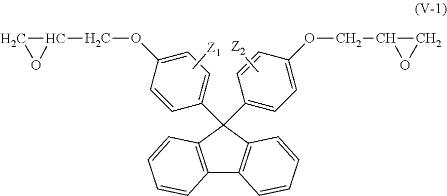

in Formula (V-1), definitions of Z₁ and Z₂ are the same as above rather than focusing or mentioned them in details.

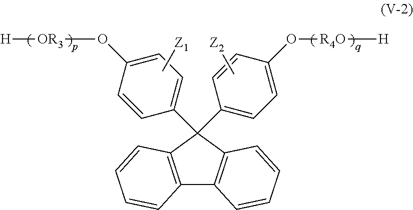

in Formula (V-2), definitions of Z₁ and Z₂ are the same as above rather than focusing or mentioned them in details. Z₃ and Z₄ respectively represent alkylene group of 1 to 20 carbons or alicyclicene group, and p and q respectively represent an integer of 1 to 4.

Examples of the aforementioned other copolymerizable compound can include monovalent carboxylic compound, such as alicyclic acid, methacrylic acid, fumaric acid, α-chloro acrylic acid, ethyl acrylic acid, cinnamic acid or the like; divalent carboxylic acid and anhydride compound thereof, such as maleic acid, itaconic acid, succinic acid, o-phthalic acid, tetrahydro phthalic acid, hexahydro phthalic acid, methyl tetrahydroxy phthalic acid, methyl hexahydro phthalic acid, methyl endo-methylene tetrahydro phthalic acid, chlorendic acid or the like; trivalent carboxylic acid and anhydride compound thereof, such as trimellitic acid or the like; tetracarboxylic acid and anhydride compound thereof, such as pyromellitic acid, benzophenone tetracarboxylic acid, biphenyl tetracarboxylic acid, biphenylether tetracarboxylic acid or the like and a combination thereof.

Preferably, the second alkali-soluble resin (A-2) can be products made by Nippon Steel Chemical Co., Ltd., and the trade name is V259ME, V301ME or the like.

Based on the total amount of the alkali-soluble resin (A) as 100 parts by weight, an amount of the second alkali-soluble resin (A-2) is 0 parts by weight to 90 parts by weight, preferably is 5 parts by weight to 88 parts by weight, and more preferably is 10 parts by weight to 90 parts by weight.

### Other Alkali-Soluble Resin (A-3)

The alkali-soluble resin (A) of the present invention can selectively include the other alkali-soluble resin (A-3). The other alkali-soluble resin (A-3) is a resin besides the first alkali-soluble resin (A-1) and the second alkali-soluble resin (A-1).

The other alkali-soluble resin (A-3) can include but be not limited to a resin having a carboxylic group or a hydroxyl group. Examples of the other alkali-soluble resin (A-3) can include acrylic acid resin, urethane resin, novolac resin and the like.

Based on the total amount of the alkali-soluble resin as 100 parts by weight, an amount of the other alkali-soluble resin (A-3) is 0 parts by weight to 30 parts by weight, preferably is 0 parts by weight to 20 parts by weight, and more preferably is 0 parts by weight to 10 parts by weight.

### Compound Having an Ethylenically Unsaturated Group (B)

the compound having an ethylenically unsaturated group (B) of the present invention can include a compound having an acidic group and at least three ethylenically unsaturated groups (B-1).

Compound Having an Acidic Group and at Least Three Ethylenically Unsaturated Groups (B-1)

An acidic group of the compound having an acidic group and at least three ethylenically unsaturated groups (B-1) can react with an alkali development agent. Examples of the acidic group can be carboxyl group, sulfo group, phosphoryl group or the like. Preferably, the acidic group can be carboxyl group that can react with the alkali development agent efficiently.

The compound having an acidic group and at least three ethylenically unsaturated groups (B-1) can be (1) a multifunctional (meth)acrylate having a hydroxy group and divalent carboxylic anhydride or divalent acid are subjected to a modified reaction to synthesize a multifunctional (meth)acrylate having a carboxyl group; or (2) an aromatic multifunctional (meth)acrylate and a concentrated sulfuric acid or a oleum are subjected to a modified reaction to synthesize a multifunctional (meth)acrylate having a sulfo group.

Preferably, the compound having an acidic group and at least three ethylenically unsaturated groups (B-1) can include a compound having a structure of Formula (VI) or (VII):

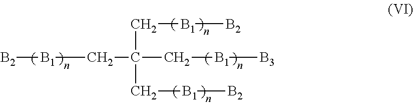

in Formula (VI), B₁ represents —CH₂—, —OCH₂—, —OCH₂CH₂—, —OCH₂CH₂CH₂— or —OCH₂CH₂CH₂CH₂—; B₂ represents a structure shown as Formula (VI-1) or (VI-2); n represents an integer of 0 to 14; and B₃ represents a structure shown as Formula (VI-3), (VI-4) or (VI-5):

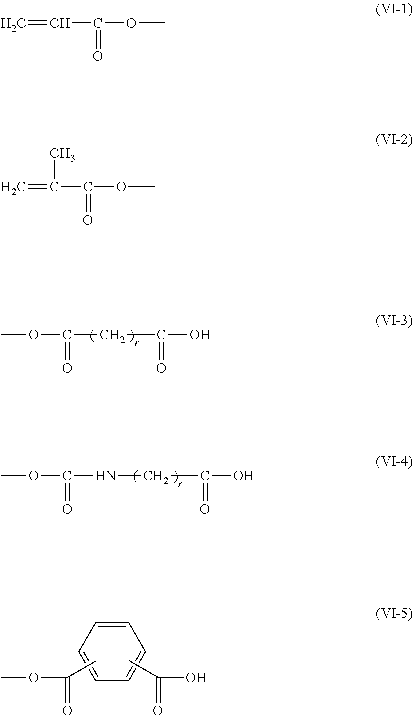

in Formula (VI-3) and (VI-4), r represents an integer of 1 to 8; in Formula (VI-5), the benzene ring can be tetra-hydrogenated or hexa-hydrogenated.

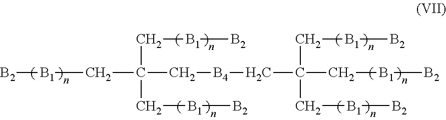

in Formula (VII), definitions of B₁, B₂, B₃, n and r are the same as above rather than focusing or mentioned them in details. B₄ represents —O— or a structure shown as Formula (VII-1), and s represents an integer of 1 to 8:

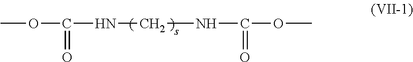

in Formula (VI) or (VII), when B₁ and B₂ are plurality, B₁ and B₂ can respectively be the same or different.

In the examples of the compound having an acidic group and at least three ethylenically unsaturated groups (B-1) shown as Formula (VI) or (VII). Examples of the compound having three ethylenically unsaturated groups can be monoester compound having a carboxyl group that is formed by monohydro oligoacrylate or monohydro oligomethacrylate, such as pentaerythritol triacrylate, pentaerythritol trimethylacrylate, dipentaerythritol pentaacrylate, dipentaerythritol pentamethylacrylate or the like, and diacid compound, such as malonic acid, butanedioic acid, glutaric acid, m-phthalic acid, p-phthalic acid, o-phthalic acid or the like; or the commercial products. The commercial products can be products made by Toagosei Co., Ltd., and the trade name is TO-756; or made by Kyoeisha Chemical Co., Ltd., and the trade name is PE3A-MS or PE3A-MP. Examples of the compound having five ethylenically unsaturated groups can be commercial products made by Toagosei Co., Ltd., and the trade name is TO-1382 or TO-1385; or made by Kyoeisha Chemical Co., Ltd., and the trade name is DPE6A-MS or DPE6A-MP.

Preferably, the compound having an acidic group and at least three ethylenically unsaturated groups (B-1) can be monoester compound having a carboxy group formed by pentaerythritol triacrylate, pentaerythritol trimethylacrylate, dipentaerythritol pentaacrylate or dipentaerythritol pentamethylacrylate and butanedioic acid or o-phthalic acid.

Based on the total amount of the alkali-soluble resin (A) as 100 parts by weight, an amount of the compound having an acidic group and at least three ethylenically unsaturated groups (B-1) is 15 parts by weight to 150 parts by weight, preferably is 20 parts by weight to 130 parts by weight, and more preferably is 25 parts by weight to 110 parts by weight.

If the compound having an ethylenically unsaturated group (B) includes the compound having an acidic group and at least three ethylenically unsaturated groups (B-1), the photosensitive resin composition will have better surface resistance.

Other Compound Having an Ethylenically Unsaturated Group (B-2)

The compound having an ethylenically unsaturated group (B) can selectively include an other compound having an ethylenically unsaturated group (B-2).

The other compound having an ethylenically unsaturated group (B-2) can be selected from a compound having an enthylenically unsaturated group or a compound having two or more enthylenically groups.

The aforementioned compound having one ethylenically unsaturated group can include but be not limited to (meth)acrylamide, (meth)acrylmorpholine, (meth)acrylic-7-ammonium-3,7-dimethyloctylester, isobutoxymethyl(meth)acrylamide, isobornyloxoethyl (meth)acrylate, isobornyl (meth)acrylate, (meth)acryl-2-hexyl acetate, ethyl diethylene glycol (meth)acrylate, ter-octyl(meth)acrylamide, dipropanone(meth)acrylamide, dimethylamineethyl (meth)acrylate, dodecane (meth)acrylate, cyclopentadienyl ethyl (meth)acrylate, cyclopentadienyl (meth)acrylate, N,N-dimethyl (meth)acryamide, tetrachlorophenyl (meth)acrylate, 2-tetrachlorophenoxyethyl (meth)acrylate, tetrahydrofurfuryl (meth)acrylate, tetrabromophenyl (meth)acrylate, 2-tetrabromophenoxyethyl (meth)acrylate, 2-trichlorophenoxyethyl (meth)acrylate, tribromophenyl (meth)acrylate, 2-tri bromophenoxyethyl (meth)acrylate, 2-hydroxy-ethyl (meth)acrylate, 2-hydro-propyl (meth)acrylate, vinyl caprolactam, N-vinyl pyrrolidone, phenoxyethyl (meth)acrylate, pentachlorophenyl (meth)acrylate, pentabromophenyl (meth)acrylate, polymonodiethyl(meth)acrylate, polymonodipropyl(meth)acrylate, bornyl (meth)acrylate or the like. the compound having one ethylenically unsaturated group can be used alone or of two or more.

The aforementioned compound having at least two (including two) ethylenically unsaturated groups can include but be not limited to ethylene glycol di(meth)acrylate, dicyclopentyl (meth)acrylate, triethylene glycol di(meth)acrylate, tetraethylene glycol di(meth)acrylate, tri(2-hydroxyethyl)isocyanic di(meth)acrylate, tri(2-hydroxyethyl)isocuanic tri(meth)acrylate, caprolactone modified tri(2-hydroxyethyl)isocuanic tri(meth)acrylate, trihydromethyl tri(meth)acrylate, ethylene oxide (EO) modified trihydromethyl tri(meth)acrylate, propylene oxide (PO) modified trihydromethyl tri(meth)acrylate, tripropylene glycol di(meth)acrylate, neopentyl glycol di(meth)acrylate, 1,4-butylene glycol di(meth)acrylate, 1,6-hexylene glycol di(meth)acrylate, polyester di(meth)acrylate, polyethylene glycol di(meth)acrylate, dipentaerythritol hexa(meth)acrylate, dipentaerythritol penta(meth)acrylate, dipentaerythritol tetra(meth)acrylate, caprolactone modified dipentaerythritol hexa(meth)acrylate, caprolactone modified dipentaerythritol penta(meth)acrylate, di(trimethylolpropane)tetra(meth)acrylate, EO modified bisphenol A di(meth)acrylate, PO modified bisphenol A di(meth)acrylate, EO modified hydrogenated bisphenol A di(meth)acrylate, PO modified hydrogenated bisphenol A di(meth)acrylate, EO modified bisphenol F di(meth)acrylate, novolac polyglycidyl methacrylate or the like. The compound having at least two (including two) ethylenically unsaturated groups can be used alone or in a combination of two or more.

Examples of the other compound having an ethylenically unsaturated group (B-2) can be trihydroxymethyl triacrylate, EO modified trihydroxymethyl triacrylate, PO modified trihydroxymethyl triacrylate, pentaerythritol tri(meth)acrylate, pentaerythritol tetra(meth)acrylate, dipentaerythritol hexa(meth)acrylate, dipentaerythritol penta(meth)acrylate, dipentaerythritol tetra(meth)acrylate, caprolactone modified dipentaerythritol hexa(meth)acrylate, ditrimethylolpropyl tetra(meth)acrylate, PO modified glycerol triacrylate or a combination thereof.

Based on the total amount of the alkali-soluble resin (A) as 100 parts by weight, an amount of the compound having an ethylenically unsaturated group (B) is 20 parts by weight to 200 parts by weight, preferably is 25 parts by weight to 180 parts by weight, and more preferably is 30 parts by weight to 160 parts by weight.

### Photo-Initiator (C)

There is no particular limitation to the photo-initiator (C) of the present invention. In a embodiment, the photo-initiator (C) can include but not be limited to an O-acyloxime compound, a triazine compound, a acetophenone compound, a diimidazole compound, a benzophenone compound, an α-diketone compound, a ketol compound, an acyloin ether compound, an acylphosphine oxide compound, a quinone compound, a halogen-containing compound, peroxide, or the like.

Specific examples of the O-oxime compound include 1-[4-(phenylthio)phenyl]-heptane-1,2-dione 2-(O-benzoyloxime), 1-[4-(phenylthio)phenyl]-octane-1,2-dione 2-(O-benzoyloxime), 1-[4-(benzoyl)phenyl]heptane-1,2-dione 2-(O-benzoyloxime), 1-[9-ethyl-6-(2-methylbenzoyl)-9H-carbazol-3-yl]-ethanone 1-(O-acetyloxime), 1-[9-ethyl-6-(3-methylbenzoyl)-9H-carbazol-3-yl]-ethanone 1-(O-acetyloxime), 1-[9-ethyl-6-benzoyl-9H-carbazol-3-yl]-ethanone 1-(O-acetyloxime), ethanone-1-[9-ethyl-6-(2-methyl-4-(tetrahydrofuranyl)benzoyl)-9H-carbazol-3-yl]-1-(O-acetyloxime), ethanone-1-[9-ethyl-6-(2-methyl-4-(tetrahydropyranyl)benzoyl)-9H-carbazol-3-yl]-1-(O-acetyl oxime), ethanone-1-[9-ethyl-6-(2-methyl-5-(tetrahydrofuranyl)benzoyl)-9H-carbazol-3-yl]-1-(O-acetyloxime), ethanone-1-[9-ethyl-6-(2-methyl-5-(tetrahydropyranyl)benzoyl)-9H-carbazol-3-yl]-1-(O-acetyloxime), ethanone-1-[9-ethyl-6-(2-methyl-4-(tetrahydrofuranyl)methoxybenzoyl)-9H-carbazol-3-yl]-1-(O-acetyloxime), ethanone-1-[9-ethyl-6-(2-methyl-4-(tetrahydropyranyl)methoxybenzoyl)-9H-carbazol-3-yl]-1-(O-acetyloxime), ethanone-1-[9-ethyl-6-(2-methyl-5-(tetrahydrofuranyl)methoxybenzoyl)-9H-carbazol-3-yl]-1-(O-acetyloxime), ethanone-1-[9-ethyl-6-(2-methyl-5-(tetrahydropyranyl)methoxybenzoyl)-9H-carbazol-3-yl]-1-(O-acetyloxime), ethanone-1-[9-ethyl-6-{2-methyl-4-(2,2-di methyl-1,3-dioxacyclopentyl)benzoyl}-9H-carbazol-3-yl]-1-(O-acetyloxime), ethanone-1-[9-ethyl-6-{2-methyl-4-(2,2-di methyl-1,3-dioxacyclopentyl)methoxybenzoyl}-9H-carbazol-3-yl]-1-(O-acetyloxime), or any combination of the above-mentioned compounds.

The O-oxime compound is preferably 1-[4-(phenylthio)phenyl]-octane-1,2-dione-2-(O-benzoyloxime) (product name: OXE-01, made by Ciba Specialty Chemicals Co., Ltd.), 1-[9-ethyl-6-(2-methylbenzoyl)-9H-carbazol-3-yl]-ethanone 1-(O-acetyloxime) (product name: OXE-02, made by Ciba Specialty Chemicals Co., Ltd.), ethanone-1-[9-ethyl-6-(2-methyl-4-(tetrahydrofuranyl)methoxybenzoyl)-9H-carbazol-3-yl]-1-(O-acetyloxime), ethanone-1-[9-ethyl-6-{2-methyl-4-(2,2-dimethyl-1,3-dioxacyclopentyl)methoxybenzoyl}-9H-carbazol-3-yl]-1-(O-acetyloxime), or any combination of the above-mentioned compounds. The 0-oxime compound can be used alone or in a combination of two or more.

Specific examples of the triazine compound include vinyl halomethyl-s-triazine compound, 2-(naphtho-1-yl)-4,6-dihalomethyl-s-triazine compound, 4-(p-aminophenyl)-2,6-dihalomethyl-s-triazine compound, or similar compound thereof, or any combination of the above-mentioned compounds.

Specific examples of the vinyl halomethyl-s-triazine compound include 2,4-bis(trichloromethyl)-6-p-methoxystyryl-s-triazine, 2,4-bis(trichloromethyl)-3-(1-p-dimethylaminophenyl-1,3-butadienyl)-s-triazine, 2-trichloromethyl-3-amino-6-p-methoxystyryl-s-triazine, or a similar compound thereof, or any combination of the above-mentioned compound.

Specific examples of the 2-(naphtho-1-yl)-4,6-dihalomethyl-s-triazine compound include 2-(naphtho-1-yl)-4,6-bis-trichloromethyl-s-triazine, 2-(4-methoxy-naphtho-1-yl)-4,6-bis-trichloromethyl-s-triazine, 2-(4-ethoxy-naphtho-1-yl)-4,6-bis-trichloromethyl-s-triazine, 2-(4-butoxy-naphtho-1-yl)-4,6-bis-trichloromethyl-s-triazine, 2-(4-(2-methoxyethyl)-naphtho-1-yl)-4,6-bis-trichloromethyl-s-triazine, 2-(4-(2-ethoxyethyl)-naphtho-1-yl)-4,6-bis-trichloromethyl-s-triazine, 2-(4-(2-butoxyethyl)-naphtho-1-yl)-4,6-bis-trichloromethyl-s-triazine, 2-(2-methoxy-naphtho-1-yl)-4,6-bis-trichloromethyl-s-triazine, 2-(6-methoxy-5-methyl-naphtho-2-yl)-4,6-bis-trichloromethyl-s-triazine, 2-(6-methoxynaphtho-2-yl)-4,6-bis-trichloromethyl-s-triazine, 2-(5-methoxy-naphtho-1-yl)-4,6-bis-trichloromethyl-s-triazine, 2-(4,7-dimethoxy-naphtho-1-yl)-4,6-bis-trichloromethyl-s-triazine, 2-(6-ethoxy-naphtho-2-yl)-4,6-bis-trichloromethyl-s-triazine, 2-(4,5-dimethoxy-naphtho-1-yl)-4,6-bis-trichloromethyl-s-triazine, or a similar compound thereof, or any combination of the above-mentioned compounds.

Specific examples of the 4-(p-aminophenyl)-2,6-dihalomethyl-s-triazine compound include 4-(p-N,N-di(ethoxycarbonylmethyl)aminophenyl)-2,6-di(trichloromethyl)-s-triazine, 4-(o-methyl-p-N,N-di(ethoxycarbonylmethyl) aminophenyl)-2,6-di(trichloromethyl)-s-triazine, 4-(p-N,N-di(chloroethyl)aminophenyl)-2,6-di(trichloromethyl)-s-triazine, 4-(o-methyl-p-N,N-di(chloroethyl)aminophenyl)-2,6-di(trichloromethyl)-s-triazine, 4-(p-N-chloroethylaminophenyl)-2,6-di(trichloromethyl)-s-triazine, 4-(p-N-ethoxy carbonylmethylaminophenyl)-2,6-di(trichloromethyl)-s-triazine, 4-(p-N,N-diphenyl)aminophenyl)-2,6-di(trichloromethyl)-s-triazine, 4-(p-N-chloroethyl carbonylaminophenyl)-2,6-di(trichloromethyl)-s-triazine, 4-(p-N-(p-methoxyphenyl)carbonylaminophenyl)-2,6-di(trichloromethyl)-s-triazine, 4-(m-N,N-di(ethoxycarbonylmethyl)aminophenyl)-2,6-di(trichloromethyl)-s-triazine, 4-(m-bromo-p-N,N-di(ethoxycarbonylmethyl)aminophenyl)-2,6-di(trichloromethyl)-s-triazine, 4-(m-chloro-p-N,N-di(ethoxycarbonylmethyl)aminophenyl)-2,6-di(trichloromethyl)-s-triazine, 4-(m-fluoro-p-N,N-di(ethoxycarbonylmethyl)aminophenyl)-2,6-di(trichloromethyl)-s-triazine, 4-(o-bromo-p-N,N-di(ethoxycarbonylmethyl)aminophenyl)-2,6-di(trichloromethyl)-s-triazine, 4-(o-chloro-p-N,N-di(ethoxycarbonylmethypaminophenyl)-2,6-di(trichloromethyl)-s-triazine, 4-(o-fluoro-p-N,N-di(ethoxycarbonylmethyl)aminophenyl)-2,6-di(trichloromethyl)-s-triazine, 4-(o-bromo-p-N,N-di(chloroethyl)aminophenyl)-2,6-di(trichloromethyl)-s-triazine, 4-(o-chloro-p-N,N-di(chloroethyl)aminophenyl)-2,6-di(trichloromethyl)-s-triazine, 4-(o-fluoro-p-N,N-di(chloroethyl)aminophenyl)-2,6-di(trichloromethyl)-s-triazine, 4-(m-bromo-p-N,N-di(chloroethyl)aminophenyl)-2,6-di(trichloromethyl)-s-triazine, 4-(m-chloro-p-N,N-di(chloroethypaminophenyl)-2,6-di(trichloromethyl)-s-triazine, 4-(m-fluoro-p-N,N-di(chloroethypaminophenyl)-2,6-di(trichloromethyl)-s-triazine, 4-(m-bromo-p-N-ethoxycarbonylmethylaminophenyl)-2,6-di(trichloromethyl)-s-triazine, 4-(m-chloro-p-N-ethoxycarbonylmethylaminophenyl)-2,6-di(trichloromethyl)-s-triazine, 4-(m-fluoro-p-N-ethoxycarbonylmethylaminophenyl)-2,6-di(trichloromethyl)-s-triazine, 4-(o-bromo-p-N-ethoxycarbonylmethylaminophenyl)-2,6-di(trichloromethyl)-s-triazine, 4-(o-chloro-p-N-ethoxycarbonylmethylaminophenyl)-2,6-di(trichloromethyl)-s-triazine, 4-(o-fluoro-p-N-ethoxycarbonylmethylaminophenyl)-2,6-di(trichloromethyl)-s-triazine, 4-(m-bromo-p-N-chloroethylaminophenyl)-2,6-di(trichloromethyl)-s-triazine, 4-(m-chloro-p-N-chloroethylaminophenyl)-2,6-di(trichloromethyl)-s-triazine, 4-(m-fluoro-p-N-chloroethylaminophenyl)-2,6-di(trichloromethyl)-s-triazine, 4-(o-bromo-p-N-chloroethylaminophenyl)-2,6-di(trichloromethyl)-s-triazine, 4-(o-chloro-p-N-chloroethylaminophenyl)-2,6-di(trichloromethyl)-s-triazine, 4-(o-fluoro-p-N-chloroethylaminophenyl)-2,6-di(trichloromethyl)-s-triazine, 2,4-di(trichloromethyl)-6-(3-bromo-4-(N,N-di(ethoxycarbonylmethyl)amino)phenyl)-1,3,5-triazine, or a similar compound thereof, or any combination of the above-mentioned compounds.

The triazine compound is preferably 4-(m-bromo-p-N,N-di(ethoxycarbonylmethyl)aminophenyl)-2,6-di(trichloromethyl)-s-triazine, 2,4-di(trichloromethyl)-6-p-methoxystyryl-s-triazine, or a combination of the above-mentioned compounds. The triazine compound can be used alone or in a combination of two or more.

Specific examples of the acetophenone compound include p-dimethylamino-acetophenone, α,α′-dimethoxyazoxy-acetophenone, 2,2′-dimethyl-2-phenyl-acetophenone, p-methoxy-acetophenone, 2-benzyl-2-N,N-dimethylamino-1-(4-morpholinophenyl)-1-butanone, 2-methyl-1-(4-methylthio phenyl)-2-morpholino-1-propanone, or a similar compound thereof, or any combination of the above-mentioned compounds. The acetophenone compound is preferably 2-methyl-1-(4-methylthio)phenyl-2-morpholinyl-1-propanone or 2-benzyl-2-N,N-dimethylamino-1-(4-morpholinophenyl)-1-butanone. The acetophenone compound can be used alone or in a combination of two or more.

Specific examples of the diimidazole compound include 2,2′-bis(o-chlorophenyl)-4,4′,5,5′-tetraphenyldiimidazole, 2,2′-bis(o-fluorophenyl)-4,4′,5,5′-tetraphenyldiimidazole, 2,2′-bis(o-methylphenyl)-4,4′,5,5′-tetraphenyldiimidazole, 2,2′-bis(o-methoxyphenyl)-4,4′,5,5′-tetraphenyl diimidazole, 2,2′-bis(o-ethylphenyl)-4,4′,5,5′-tetraphenyldiimidazole, 2,2′-bis(p-methoxyphenyl)-4,4′,5,5′-tetraphenyldiimidazole, 2,2′-bis(2,2′,4,4′-tetramethoxyphenyl)-4,4′,5,5′-tetraphenyldiimidazole, 2,2′-bis(2-chlorophenyl)-4,4′,5,5′-tetraphenyldiimidazole, 2,2′-bis(2,4-dichlorophenyl)-4,4′,5,5′-tetraphenyldiimidazole or the like, or any combination of the above-mentioned compounds. The diimidazole compound can be used alone or in a combination of two or more. The diimidazole compound is preferably 2,2′-bis(2,4-dichlorophenyl)-4,4′,5,5′-tetraphenyldiimidazole.

Specific examples of the benzophenone compound include thioxanthone, 2,4-diethylthioxanthone, thioxanthone-4-sulfone, benzophenone, 4,4′-bis(dimethylamino)benzophenone, 4,4′-bis(diethylamino)benzophenone, or a similar compound thereof, or any combination of the above-mentioned compounds. The benzophenone compound can be used alone or in a combination of two or more. The benzophenone compound is preferably 4,4′-bis(diethylamino)benzophenone.

Specific examples of the α-diketone compounds include diphenyl-ethanedione or a compound having an acetyl group.

Specific examples of the acyloin ether compound include benzoin.

Specific examples of the acyloin ether compound include benzoin methyl ether, benzoin ethyl ether, benzoin isopropyl ether, or a similar compound thereof, or any combination of the above-mentioned compounds.

Specific examples of the acylphosphine oxide compound include (2,4,6-trimethylbenzoyl)diphenylphosphine oxide, bis(2,6-dimethoxybenzoyl)-2,4,4-trimethylpentylphosphine oxide, or a similar compound thereof, or any combination of the above-mentioned compounds.

Specific examples of the quinone compound include anthraquinone, 1,4-naphthoquinone, or a similar compound thereof, or any combination of the above-mentioned compounds.

Specific examples of the halogen-containing compound include phenacyl chloride, tribromomethyl phenyl sulfone, tris(trichloromethyl)-s-triazine, or a similar compound thereof, or any combination of the above-mentioned compounds.

Specific examples of the peroxide include di-tert-butyl peroxide and a similar compound thereof.

The photoinitiator (C) is preferably 1-[9-ethyl-6-(2-methylbenzoyl)-9H-carbazol-3-yl]-ethanone 1-(O-acetyloxime) (product name: OXE-02, made by Ciba Specialty Chemicals Co., Ltd.), 1-[4-(phenylthio)phenyl]-octane-1,2-dione 2-(O-benzoyloxime) (product name: OXE-01, made by Ciba Specialty Chemicals Co., Ltd.), 2-methyl-1-[4-(methylthio)phenyl]-2-morpholino-1-propanone (product name: IRGACURE 907, made by Ciba Specialty Chemicals Co., Ltd.), or any combination of the above-mentioned compounds.

Based on the total amount of the alkali-soluble resin (A) as 100 parts by weight, an amount of the photo-initiator (C) is 5 parts by weight to 55 parts by weight, preferably is 7 parts by weight to 50 parts by weight, and more preferably is 10 parts by weight to 45 parts by weight.

### Solvent (D)

The solvent (D) of the present invention refers to a solvent that can dissolve the alkali-soluble resin (A), the compound having an ethylenically unsaturated group (B) and the photo-initiator (C), and the following black pigment (E) and the oxetane compound having a silicon atom (F). The solvent (D) would not react with the aforementioned compositions. The solvent (D) preferably has suitable volatility.

For examples, the solvent (D) can include alkyl glycol monoalkyl ether compound, such as ethylene glycol monomethyl ether, ethylene glycol monoethyl ether, diethylene glycol monoethyl ether, diethylene glycol mono-n-propyl ether, diethylene glycol mono-n-butyl ether, triethylene glycol monomethyl ether, triethylene glycol monoethyl ether, propylene glycol monomethyl ether, propylene glycol monoethyl ether, dipropylene glycol monomethyl ether, dipropylene glycol monoethyl ether, dipropylene glycol mono-n-propyl ether, dipropylene glycol mono-butyl ether, tripropylene glycol monomethyl ether, tripropylene glycol monoethyl ether or the like; alkyl glycol monoalkyl ether acetate compound, such as ethylene glycol monomethyl ether acetate, ethylene glycol monoethyl ether acetate, propylene glycol monomethyl ether acetate, propylene glycol monoethyl ether acetate or the like; diethylene glycol alkyl ether, such as diethylene glycol dimethyl ether, diethylene glycol ethyl methyl ether, diethylene glycol diethyl ether or the like; other ether compounds, such as tetrahydrofuran or the like; ketone compound, such as methyl ethyl ketone, cyclohexanone, 2-heptanone, 3-heptanone, diacetone alcohol or the like; alkyl lactate compound, such as methyl lactate, ethyl lactate or the like; other ester compounds, such as methyl 2-hydroxy-2-methylpropanoate, ethyl 2-hydroxy-2-methylpropanoate, methyl 3-methoxypropanoate, ethyl 3-methoxypropanoate, methyl 3-ethoxypropanoate, ethyl 3-ethoxypropanoate, ethyl ethoxyacetate, ethyl hydroxyacetate, methyl 2-hydroxy-3-methylbutyrate, 3-methyl-3-methoxybutyl acetate, 3-methyl-3-methoxybutyl propanoate, ethyl acetate, n-propyl acetate, isopropyl acetate, n-butyl acetate, isobutyl acetate, n-amyl acetate, isoamyl acetate, n-butyl propanoate, ethyl butyrate, n-propyl butyrate, isopropyl butyrate, n-butyl butyrate, methyl pyruvate, ethyl pyruvate, n-propyl pyruvate, methyl acetoacetate, ethyl acetoacetate, ethyl 2-oxybutyrate or the like; aromatic hydrocarbon compound, such as toluene, xylene or the like; carboxylic acid amine compound, such as N-methylpyrrolidone, N,N-dimethyl formamide, N,N-dimethyl acetamide or the like. The aforementioned solvent (D) can be used alone or a combination of two or more.

Based on the total amount of the alkali-soluble resin (A) as 100 parts by weight, an amount of the solvent (D) is 1000 parts by weight to 5000 parts by weight, preferably is 1100 parts by weight to 4500 parts by weight, and more preferably is 1200 parts by weight to 4000 parts by weight.

### Black Pigment (E)

The black pigment (E) of the present invention is a black pigment with thermal resistance property, photo resistance property and solvent resistance property.

For examples, the black pigment (E) can include black organic pigment, such as perylene black, cyanine black, aniline black or the like; a near-black mixing organic pigments obtained by mixing two or more pigments selected from the pigments of red, blue, green, purple, yellow, cyanine, magenta or the like; light-shielding material, such as carbon black, chromium oxide, ferric oxide, titanium black, graphite or the like. For example, the aforementioned carbon black can include C.I.pigment black 7 or the like. The aforementioned carbon black can include commercial products made by Mitsubishi Chemical Corporation, and the trade name is MA100, MA230, MA8, #970, #1000, #2350, or #2650. The black pigment (E) can be used alone or in a combination of two or more.

Based on the total amount of the alkali-soluble resin (A) as 100 pats by weight, an amount of the black pigment (E) is 60 parts by weight to 600 parts by weight, preferably is 80 parts by weight to 550 parts by weight, and more preferably is 100 parts by weight to 500 parts by weight.

### Oxetane Compound Having a Silicon Atom (F)

The oxetane compound having a silicon atom (F) of the present invention can include a first oxetane compound having a silicon atom (F-1), a second oxetane compound having a silicon atom (F-2) or a combination thereof.

### First Oxetane Compound Having a Silicon Atom (F-1)

The first oxetane compound having a silicon atom (F-1) is a compound having a structure of Formula (II) or a condensate of the compound having a structure of Formula (II):

Si(Y₁)ₐ(OY₂)₄₋ₐ (II)

in the Formula (II), Y₁ and Y₂ respectively represent an alkyl group of 1 to 8 carbons, a cycloalkyl group of 6 to 10 carbons, an aromatic of 6 to 10 carbons, an alkyl carbonyl group of 2 to 7 carbons or an organic group having an oxetanyl group; at least one of Y₁ and Y₂ is the organic group having an oxetanyl group; and a represents an integer of 0 to 3.

For example, the compound having a structure of Formula (II) can include but be not limited to 3-[(3-ethyloxetane-3-yl)methoxy]propyl trimethoxy silane, 3-[(3-ethyloxetane-3-yl)methoxy]propyl triethoxy silane, 3-[(3-ethyloxetane-3-yl)methoxy]propyl triacetoxy silane, 3-[(3-ethyloxetane-3-yl)methoxy]propyl methyl diethoxy silane, 3-[(3-ethyloxetane-3-yl)methoxy]propyl methyl diacetoxy silane, 3-[(3-ethyloxetane-3-yl)methoxy]propyl dimethyl methoxy silane, 3-[(3-ethyloxetane-3-yl)methoxy]propyl dimethyl ethoxy silane, 3-[(3-ethyloxetane-3-yl)methoxy]propyl dimethyl acetoxy silane, (3-ethyloxetane-3-yl)methoxy trimethoxy silane, (3-ethyloxetane-3-yl)methoxy triethoxy silane, di[(3-ethyloxetane-3-yl)methoxy]dimethoxy silane, di[(3-ethyloxetane-3-yl)methoxy]diethoxy silane, tri[(3-ethyloxetane-3-yl)methoxy]methoxy silane, tri[(3-ethyloxetane-3-yl)methoxy]ethoxy silane or a combination thereof. In view point of hydrolysis, the compound having a structure of Formula (II) preferably can include methoxy group.

Second Oxetane Compound Having a Silicon Atom (F-2)

The second oxetane compound having a silicon atom (F-2) is obtained by subjected a compound having a structure of Formula (III) to a thermal condensation reaction, and then subjected to an ester-interchange reaction with an oxetane compound having a hydroxyl group having a structure of Formula (IV):

Si(Y₃)_{b}(OY₄)_{4-b} (III)

in the Formula (III), Y₃ respectively represents an alkyl group of 1 to 8 carbons, a cycloalkyl group of 6 to 10 carbons or an aromatic group of 6 to 10 carbons; Y₄ respectively represents an alkyl group of 1 to 8 carbons, a cycloalkyl group of 6 to 10 carbons, an aromatic group of 6 to 10 carbons or an alkyl carbonyl group of 2 to 5 carbons; and b represents an integer of 0 to 2;

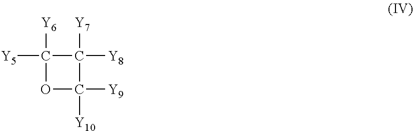

in the Formula (IV), Y₅ to Y₁₀ respectively represents a hydrogen atom, a fluorine atom, an alkyl group of 1 to 4, an alkyl group having a hydroxyl group or a phenyl group; and at least one of Y₅ to Y₁₀ represents the alkyl group having a hydroxyl group.

Examples of the compound having a structure of Formula (III) can include tetramethoxy silane, tetraethoxy silane, methyl trimethoxy silane, methyl triethoxy silane, methyl triacetoxy silane, ethyl trimethoxy silane, ethyl triethoxy silane, ethyl triacetoxy silane, propyl trimethoxy silane, propyl triethoxy silane, cyclohexyl trimethoxy silane, phenyl trimethoxy silane, phenyl triethoxy silane, dimethyl dimethoxy silane, dimethyl diethoxy silane, diethyl dimethoxy silane, diethyl diethoxy silane or a combination thereof. In view point of lower steric hindrance of the ester-interchange reaction, the compound having a structure of Formula (III) preferably can be tetramethoxy silane, tetarethoxy silane, methyl trimethoxy silane, methyl triethoxy silane, ethyl trimethoxy silane, ethyl triethoxy silane or a combination thereof.

In view point of synthesizing easily, examples of the oxetane compound having a hydroxyl group having a structure of Formula (IV) can include (3-methyloxetane-3-yl)methanol, (3-ethyloxetane-3-yl)methanol, 2-hydroxymethyloxetane or a combination thereof.

Preferably, a weight-average molecule weight of the oxetane compound having a silicon atom (F) is 200 to 4000.

Based on the total amount of the alkali-soluble (A) as 100 parts by weight, an amount of the oxetane compound having a silicon atom (F) is 1 part by weight to 10 parts by weight, preferably is 1.2 parts by weight to 9 parts by weight, and more preferably is 1.5 parts by weight to 8 parts by weight.

When a following post-baking treatment is performed, the oxetane compound having a silicon atom (F) can provide better protection to the aforementioned black pigment (E), thereby increasing the surface resistance.

When the photosensitive resin composition does not include the oxetane compound having a silicon atom (F), the photosensitive resin composition has a defect of poor surface resistance.

### Compound Having at Least Two Oxirane Groups in a Molecule (G)

The photosensitive resin composition of the present invention can selectively include a compound having at least two oxirane groups in a molecule (G).

For example, the compound having at least two oxirane groups in a molecule (G) can include bisphenol A epoxyethane, bisphenol F epoxyethane, phenol novolac epoxyethane, cresol novolac epoxyethane, aliphatic novolac epoxyethane or the like.

The compound having at least two oxirane groups in a molecule (G) can include the commercial products made by Mitsubishi Chemical Co., Ltd., and the trade name is JER152, JER157S70, JER157S65, JER806, JER828, JER1007 or the like; disclosed at paragraph [0189] of Japan Patent Laid Open No. 2011-221494; made by Nagase ChemteX Co., Ltd., and the trade name is DENACOL EX-611, EX-612, EX-614, EX-614B, EX-622, EX-512, EX-521, EX-411, EX-421, EX-313, EX-314, EX-321, EX-211, EX-212, EX-810, EX-811, EX-850, EX-851, EX-821, EX-830, EX-832, EX-841, EX-911, EX-941, EX-920, EX-931, EX-212L, EX-214L, EX-216L, EX-321L, EX-850L, DLC-201, DLC-203, DLC-204, DLC-205, DLC-206, DLC-301, DLC-402 or the like; made by Nippon Steel Chemical Co., Ltd., and the trade name is YH-300, YH-301, YH-302, YH-315, YH-324, YH-325 or the like.

The compound having at least two oxirane groups in a molecule (G) can be used alone or in a combination of two or more.

Based on the total amount of the alkali-soluble resin (A) as 100 parts by weight, an amount of the compound having at least two oxirane groups in a molecule (G) is 30 parts by weight to 120 parts by weight, preferably is 35 parts by weight to 110 parts by weight, and more preferably is 40 parts by weight to 100 parts by weight.

When the following post-baking treatment is performed, the compound having at least two oxirane groups in a molecule (G) can provide better protection to the aforementioned black pigment (E), thereby increasing the surface resistance.

When the photosensitive resin composition includes the compound having at least two oxirane groups in a molecule (G), the photosensitive resin composition has better surface resistance.

### Additive (H)

Under the premise without affecting the efficacy of the present invention, the photosensitive resin composition for the black matrix of the present invention can selectively further include the additive (H). The examples of the additive (H) can include but be not limited to a surfactant, a filler, an adhesion promoter, an antioxidant, an anticoagulant.

For example, the aforementioned surfactant can include a cationic surfactant, an anionic surfactant, a nonionic surfactant, an amphoteric surfactant, a polysiloxane surfactant, a fluorine-containing surfactant or a combination thereof.

For example, the surfactant can include but be not limited to polyoxyethylene alkyl ethers, such as polyoxyethylene lauryl ether, polyoxyethylene stearyl ether, polyoxyethylene oleyl ether or the like; polyoxyethylene alkyl phenyl ethers, such as polyoxyethylene octyl phenyl ether, polyoxyethylene nonyl phenyl ether or the like; polyethylene glycol diesters, such as polyethylene glycol dilaurate, polyethylene glycol stearyl ether or the like; sorbitan fatty acid esters; fatty acid-modified polyesters; tertiary amine-modified polyurethanes or commercial products. The commercial products can include products made by Shin-Etsu Chemical Co., Ltd., and the trade name is KP; products made by Dow Corning Toray Co., Ltd., and the trade name is SF-8427; products made by Kyoeisha Chemical Co. Ltd., and the trade name is Polyflow; products made by Tochem Products Co., Ltd., and the trade name is F-Top; products made by DIC Corporation, and the trade name is Megafac; products made by Sumitomo 3M Limited, and the trade name is Fluorade; products made by Asahi Glass Co., Ltd., and the trade name is Asahi Guard or Surflon; or products made by Sino-Japan chemical Co., LTD., and the trade name is SINOPOL E8008. The surfactant can be used alone or in a combination of two or more.

The aforementioned fluorine-containing surfactant can include but be not limited to 1,1,2,2-tetrafluorooctyl(1,1,2,2-tetrafluoropropyl)ether, 1,1,2,2-tetrafluorooctylhexylether, decylethylene glycol bis(1,1,2,2-tetrafluorobutyl)ether, hexaethylene glycol(1,1,2,2,3,3-hexafluoropentyl)ether, decylpropene glycol bis(1,1,2,2-tetrafluorobutyl)ether, hexapropene glycol(1,1,2,2,3,3-hexafluoropentyl)ether, perfluorododecy sodium sulfate, 1,1,2,2,8,8,9,9,10,10-octylfluorododecane, 1,1,2,2,3,3-hexafluorodecane, fluoroalkanephenyl sodium sulfate, fluoroalkane sodium phosphate, fluoroalkane sodium carboxylat, fluoroalkane polyethylene oxide, diglycoltetra(fluoroalkane polyethylene oxide), fluoroalkane ammonium iodide, fluoroalkane betaine, pertfluoroalkane polyethylene oxide, pertfluoroalkane alkanol, or the commercial products. The commercial products can be made by BM CHEMIE Co., Ltd., and the trade name is BM-1000 or BM-1100; made by Dainippon Ink and Chemicals, Inc., and the trade name is Megafac F142D, F172, F173, F183, F178, F191, F471 or F476; made by Sumitomo Chemical Co., Ltd., and the trade name is Fluorad FC 170C, FC-171, FC-430 or FC-431; made by Asahi Glass Co., Ltd., and the trade name is chloride fluorine carbon S-112, S-113, S-131, S-141, S-145, S-382, SC-101, SC-102, SC-103, SC-104, SC-105 or SC-106; made by Akita Kasei Co., Ltd., and the trade name is F Top EF301, 303 or 252; made by NEOSU Co., Ltd., and the trade name is Ftergent FT-100, FT-110, FT-140A, FT-150, FT-250, FT-251, FTX-251, FTX-218, FT-300, FT-310 or FT-400S; or made by DIC Co., Ltd., and the trade name is F-410, F-444, F-552, F-553 or F-554. The fluorine-containing surfactant can be used alone or in a combination of two or more.

The examples of the filler can include glass, aluminum or the like.

The examples of the adhesion promoter can include melamine compound, silane compound and the like. The adhesion promoter can enhance the adhesion property between the photosensitive resin composition and the substrate having the semiconductor material. The melamine can include but be not limited to products made by Mitsui Chemicals Inc., and the trade name is Cymel-300, Cymel-303 or the like; products made by Sanwa Chemistry Co., Ltd., and the trade name is MW-30MH, MW-30, MS-11, MS-001, MX-750, MX-706 or the like. The silane compound can include but be not limited to vinyltrimethoxysilane, vinyltriethoxysilane, 3-(methyl)propionyloxy propyltrimethoxysilane, vinyl-tris(2-methoxyethoxy)silane, N-(2-amino ethyl)-3-aminopropylmethyldimethoxysilane, N-(2-aminoethyl)-3-aminopropyltrimethoxysilane, 3-aminopropyltriethoxysilane, 3-glycidoxypropyltrimethoxysilane, 3-glycidolpropyltrimethoxysilane, 3-glycidoxypropyldimethylmethoxysilane, 3-glycidolpropylmethyldiethoxysilane, 2-(3,4-epoxycyclohexyl)ethyltrimethoxysilane, 3-chloropropylmethyldimethoxysilane, 3-chloropropyltrimethoxysilane, 3-methylpropenyloxopropyltrimethoxysilane, 3-methacryloxypropyltrimethoxysilane, 3-mercaptopropyltrimethoxysilane or products made by Shin-Etsu Chemical Co., Ltd., and the trade name is KBM-403.

The examples of the antioxidant can include 2,2′-thiobis(4-methyl-6-tert-butylphenol), 2,6-di-tert-butylphenol or the like.

The examples of the anticoagulant can include sodium polyacrylate or the like.

Based on the total amount of the alkali-soluble resin (A) as 100 parts by weight, an amount of the filler, the adhesion promoter, the antioxidant or the anticoagulant of the additive (H) is less than or equal to 10 parts by weight, and preferably is less than or equal to 6 parts by weight.

Based on the total amount of the alkali-soluble resin (A) as 100 parts by weight, an amount of the surfactant of the additive (H) is less than or equal to 6 parts by weight, and preferably is less than or equal to 4 parts by weight.

Producing Photosensitive Resin Composition for Black Matrix

The photosensitive resin composition for the black matrix is manufactured by mixing the alkali-soluble resin (A), the compound having an ethylenically unsaturated group (B), the photo-initiator (C), the solvent (D), the black pigment (E), and the oxetane compound having a silicon atom (F) in a mixer uniformly to form a solution. If necessary, the compound having at least two oxirane groups in a molecule (G) and the additive (H) can optionally be added. After the compositions are mixed uniformly, the photosensitive resin composition for the black matrix can be obtained.

Based on the total amount of the alkali-soluble resin (A) as 100 parts by weight, the amount of the compound having an ethylenically unsaturated group (B) is 20 parts by weight to 200 parts by weight, the amount of the photo-initiator (C) is 5 parts by weight to 55 parts by weight, the amount of the solvent (D) is 1000 parts by weight to 5000 parts by weight, the amount of the black pigment (E) is 60 parts by weight to 600 parts by weight, and the amount of the oxetane compound having a silicon atom (F) is 1 part by weight to 10 parts by weight.

Moreover, based on the total amount of the alkali-soluble resin (A) is 100 parts by weight, the amount of the compound having an acidic group and at least three ethylenically unsaturated groups (B-1) is 15 parts by weight to 150 parts by weight, and the amount of the compound having at least two oxirane groups in a molecule (G) is 30 parts by weight to 120 parts by weight.

### Producing Black Matrix

The black matrix is produced by subjecting the photosensitive resin composition for the black matrix to a pre-bake treatment, an exposure treatment, a development treatment, and a post-bake treatment. When the film thickness of the black matrix is 1 μm, the optical density is greater than or equal to 3.0. Preferably, when the film thickness of the black matrix is 1 μm, the optical density is 3.2 to 5.5. More preferably, when the film thickness of the black matrix is 1 μm, the optical density is 3.5 to 5.5.

The black matrix of the present invention can be formed by a coating method, such as spin-coating, cast-coating or the like. The photosensitive resin composition of the present invention is coated onto a substrate, and the solvent is removed by drying under reduced pressure and the pre-bake treatment, thereby forming a pre-baked coating film on the substrate. According to the difference of the kinds of the compositions and the ratio thereof, the aforementioned drying under reduced pressure and the pre-bake treatment has different manufacturing conditions. The drying under reduced pressure is usually performed for 1 second to 20 seconds at a pressure lower than 20 mmHg, and the pre-bake treatment is performed for 1 minute to 15 minutes at 70° C. to 110° C. After the pre-bake treatment is performed, the aforementioned coating film is subjected to the exposure treatment under a desired mask. Then, the exposed coating film is immersed into a development agent at 21° C. to 25° C. for 15 seconds to 5 minutes to remove undesired portions, thereby forming a specific pattern. The light used in the exposure treatment is preferably an ultraviolet light, such as g-line, h-line, i-line or the like, and the ultraviolet light irradiating device can be a(n) (ultra-)high pressure mercury vapor lamp and a metal halide lamp.

For example, the suitable development agent can be an alkali compound, such as sodium hydroxide, potassium hydroxide, sodium carbonate, sodium hydrogen carbonate, potassium carbonate, potassium hydrogen carbonate, sodium silicate, sodium methylsilicate, ammonia solution, ethylamine, diethylamine, dimethylethylanolamine, tetramethylammonium hydroxide, tetraethylammonium hydroxide, choline, pyrrole, piperidine, 1,8-diazabicyclo-[5,4,0]-7-undecene or the like. A concentration of the development agent is generally 0.001 wt % to 10 wt %, preferably is 0.005 wt % to 5 wt %, and more preferably is 0.01 wt % to 1 wt %.

When the aforementioned development agent is used, the pattern is rinsed with water after the development treatment, and then dried with compressed air or compressed nitrogen. Next, the post-bake treatment is performed with a heating device, such as a hot plate or an oven. The temperature of the post-bake treatment is 150° C. to 250° C. The heating period is 5 minutes to 60 minutes for the hot plate, and the heating period is 15 minutes to 150 minutes for the oven. The black matrix can be formed on the substrate after the aforementioned treating processes.

For example, the aforementioned substrate can be alkali-free glass, soda-lime glass, hard glass (Pyrex glass), silica glass, and glasses with a transparent conductive film attached thereto, or a substrate (e.g., a silicon substrate) used for a photoelectric conversion device such as a solid imaging device.

### Producing Method of Color Filter

The producing method of the color filter of the present invention is applying a photosensitive resin composition for the color filter onto the substrate by a coating method, such as spin-coating, cast-coating, roller-coating or the like. The black matrix for separating the pixel coloring layer has been formed on the substrate. After the coating method is performed, most portions of the solvent are removed by drying under reduced pressure. Then, the residual solvent is removed by pre-bake to form a pre-baked coating film. According to the difference of the kinds of the compositions and the ratio thereof, the aforementioned drying under reduced pressure and the pre-bake treatment has different manufacturing conditions. The drying under reduced pressure is usually performed for 1 second to 60 seconds at 0 mmHg to 200 mmHg, and the pre-bake treatment is performed for 1 minute to 15 minutes at 70° C. to 110° C. After the pre-bake treatment is performed, the aforementioned coating film is subjected to the exposure treatment under a desired mask. Then, the exposed coating film is immersed into a development agent at 21° C. to 25° C. for 15 seconds to 5 minutes to remove undesired portions, thereby forming a specific pattern. The light used in the exposure treatment is preferably an ultraviolet light, such as g-line, h-line, i-line or the like, and the ultraviolet light irradiating device can be a(n) (ultra-)high pressure mercury vapor lamp and a metal halide lamp.

After the aforementioned development treatment, the pattern is rinsed with water, and then dried with compressed air or compressed nitrogen. Next, a post-bake treatment is performed by the heating device, such as a hot plate, an oven or the like. The conditions of the post-bake treatment are descried as the above rather than focusing or mentioning them in details.

Each color (major including red, green and blue) repeats the aforementioned process, and the pixel layer of the color filter can be obtained. Moreover, in a vacuum environment, an ITO deposited film is formed on the pixel layer. If necessarily, after the etching and laying treatment are performed to the ITO deposited film, polyimide for liquid crystal alignment film is coated, and further firing, thereby forming a color filter for a liquid crystal display device.

### Producing Method of Liquid Crystal Display Device

The liquid crystal display device includes the color filter substrate formed by the aforementioned producing method of the color filter and a driving substrate disposed thin film transistor (TFT). Then, a gap (cell gap) is inserted into the aforementioned two substrates oppositely disposed. The surrounding area of the aforementioned two substrates is adhered by an adhesive agent. The liquid crystal is injected into the gap formed by the surfaces of the substrate and the adhesive agent. Next, the liquid crystal injecting hole is sealed to form a liquid crystal cell. And then, polarized plates are adhered onto the outer-surfaces of the liquid crystal cell, that is to say the other surface of the substrates utilized to form the liquid crystal cell, thereby obtaining the liquid crystal display device.

There are no particular limitations to the liquid crystal, that is to say the liquid crystal compound or the liquid crystal composition. Those can be one of any the liquid crystal compound or the liquid crystal composition.

Moreover, the aforementioned liquid crystal alignment film is used to limit the aligning of the liquid crystal molecule. There are no particular limitations to that, and that can be any of inorganic compound or organic compound. The method for producing the liquid crystal alignment film is general for one skilled in the art, and that is not the feature of the present invention rather than focusing or mentioned them in details.

Several embodiments are described below to illustrate the application of the present invention. However, these embodiments are not used for limiting the present invention. For those skilled in the art of the present invention, various variations and modifications can be made without departing from the spirit and scope of the present invention.

### DETAILED DESCRIPTION

### Producing Glycol Compound Having a Polymeric Unsaturated Group (a-1)

### Producing Example 1

Firstly, 100 parts by weight of a fluorene epoxy compound (made by Nippon Steel Chemical Co., Ltd., and the trade name is ESF-300; epoxy equivalent: 231), 30 parts by weight of acrylic acid, 0.3 parts by weight of benzyltriethylammonium chloride, 0.1 parts by weight of 2,6-di-t-butyl-p-cresol and 130 parts by weight of propylene glycol monomethyl ether acetate were continuously added in a 500 ml four neck flask. The feeding speed was controlled at 25 parts by weight per minute, and the temperature of the reaction is maintained at 100° C. to 110° C. After 15 hours, a light yellow mixture having a solid component concentration of 50 wt % could be obtained. Then, the light yellow mixture was subjected to steps, such as extract, flitting and drying, thereby obtain a glycol compound having a polymeric unsaturated group (a-1-1) of Producing Example 1 having a solid component concentration of 99.9 wt %.

### Producing Example 2

Firstly, 100 parts by weight of a fluorene epoxy compound (made by Osaka Gas Co., Ltd., and the trade name is PG-100; epoxy equivalent: 259), 35 parts by weight of mathacrylic acid, 0.3 parts by weight of benzyltriethylammonium chloride, 0.1 parts by weight of 2,6-di-t-butyl-p-cresol and 135 parts by weight of propylene glycol monomethyl ether acetate were continuously added in a 500 ml four neck flask. The feeding speed was controlled at 25 parts by weight per minute, and the temperature of the reaction is maintained at 100° C. to 110° C. After 15 hours, a light yellow mixture having a solid component concentration of 50 wt % could be obtained. Then, the light yellow mixture was subjected to steps, such as extract, flitting and drying, thereby obtain a glycol compound having a polymeric unsaturated group (a-1-2) of Producing Example 2 having a solid component concentration of 99.9 wt %.

### Producing Example 3

Firstly, 100 parts by weight of a fluorene epoxy compound (made by Nippon Steel Chemical Co., Ltd., and the trade name is ESF-300; epoxy equivalent: 231), 100 parts by weight of 2-methacryloyloxyethylbutanedioic acid, 0.3 parts by weight of benzyltriethylammonium chloride, 0.1 parts by weight of 2,6-di-t-butyl-p-cresol and 200 parts by weight of propylene glycol monomethyl ether acetate were continuously added in a 500 ml four neck flask. The feeding speed was controlled at 25 parts by weight per minute, and the temperature of the reaction is maintained at 100° C. to 110° C. After 15 hours, a light yellow mixture having a solid component concentration of 50 wt % could be obtained. Then, the light yellow mixture was subjected to steps, such as extract, flitting and drying, thereby obtain a glycol compound having a polymeric unsaturated group (a-1-3) of Producing Example 3 having a solid component concentration of 99.9 wt %.

### Producing Example 4

Firstly, in a 1000 ml three neck flask equipping a mechanical stirrer, a temperature meter and a condenser, 0.3 moles of bis(4-hydroxyphenyl)sulfone, 9 moles of 3-chloro-1,2-epoxypropane and 0.003 moles of tetramethyl ammonium chloride were added. Then, the solution was stirred to 105° C. After the solution was reacted at 105° C. for 9 hours, the unreacted 3-chloro-1,2-epoxypropane was distilled under reduced pressure. Next, the reacted solution was cooled to room temperature, and 9 moles of benzene and 0.5 moles of sodium hydroxide (dissolved in water and the concentration was 30 wt %) were added into the reacted solution when the solution was stirred. The solution was heated to and maintained at 60° C. for 3 hours. And then, the solution was rinsed by water repeatedly until the chloride ion was non-existing (detected by silver nitrate). The benzene was removed by distilling under reduced pressure, and drying at 75° C. for 24 hours, thereby obtaining a epoxy compound of bis(4-hydroxyphenyl)sulfone.

100 parts by weight of the epoxy compound of bis(4-hydroxyphenyl)sulfone (epoxy equivalent is 181), 30 parts by weight of acrylic acid, 0.3 parts by weight of benzyltriethylammonium chloride, 0.1 parts by weight of 2,6-di-t-butyl-p-cresol and 130 parts by weight of propylene glycol monomethyl ether acetate were continuously added in a 500 ml four neck flask. The feeding speed was controlled at 25 parts by weight per minute, and the temperature of the reaction is maintained at 100° C. to 110° C. After 15 hours, a light yellow mixture having a solid component concentration of 50 wt % could be obtained. Then, the light yellow mixture was subjected to steps, such as extract, flitting and drying, thereby obtain a glycol compound having a polymeric unsaturated group (a-1-4) of Producing Example 4 having a solid component concentration of 99.9 wt %.

### Producing Example 5

Firstly, in a 1000 ml three neck flask equipping a mechanical stirrer, a temperature meter and a condenser, 0.3 moles of bis(4-hydroxyphenyl)hexafluoropropane, 9 moles of 3-chloro-1,2-epoxypropane and 0.003 moles of tetramethyl ammonium chloride were added. Then, the solution was stirred to 105° C. After the solution was reacted at 105° C. for 9 hours, the unreacted 3-chloro-1,2-epoxypropane was distilled under reduced pressure. Next, the reacted solution was cooled to room temperature, and 9 moles of benzene and 0.5 moles of sodium hydroxide (dissolved in water and the concentration was 30 wt %) were added into the reacted solution when the solution was stirred. The solution was heated to and maintained at 60° C. for 3 hours. And then, the solution was rinsed by water repeatedly until the chloride ion was non-existing (detected by silver nitrate). The benzene was removed by distilling under reduced pressure, and drying at 75° C. for 24 hours, thereby obtaining a epoxy compound of bis(4-hydroxyphenyl)hexafluoropropane.

100 parts by weight of the epoxy compound of bis(4-hydroxyphenyl)hexafluoropropane (epoxy equivalent is 224), 35 parts by weight of methacrylic acid, 0.3 parts by weight of benzyltriethylammonium chloride, 0.1 parts by weight of 2,6-di-t-butyl-p-cresol and 135 parts by weight of propylene glycol monomethyl ether acetate were continuously added in a 500 ml four neck flask. The feeding speed was controlled at 25 parts by weight per minute, and the temperature of the reaction is maintained at 100° C. to 110° C. After 15 hours, a light yellow mixture having a solid component concentration of 50 wt % could be obtained. Then, the light yellow mixture was subjected to steps, such as extract, flitting and drying, thereby obtain a glycol compound having a polymeric unsaturated group (a-1-5) of Producing Example 5 having a solid component concentration of 99.9 wt %.

### Producing Example 6

Firstly, in a 1000 ml three neck flask equipping a mechanical stirrer, a temperature meter and a condenser, 0.3 moles of bis(4-hydroxyphenyl)dimethyl silane, 9 moles of 3-chloro-1,2-epoxypropane and 0.003 moles of tetramethyl ammonium chloride were added. Then, the solution was stirred to 105° C. After the solution was reacted at 105° C. for 9 hours, the unreacted 3-chloro-1,2-epoxypropane was distilled under reduced pressure. Next, the reacted solution was cooled to room temperature, and 9 moles of benzene and 0.5 moles of sodium hydroxide (dissolved in water and the concentration was 30 wt %) were added into the reacted solution when the solution was stirred. The solution was heated to and maintained at 60° C. for 3 hours. And then, the solution was rinsed by water repeatedly until the chloride ion was non-existing (detected by silver nitrate). The benzene was removed by distilling under reduced pressure, and drying at 75° C. for 24 hours, thereby obtaining a epoxy compound of bis(4-hydroxyphenyl)dimethyl silane.

100 parts by weight of the epoxy compound of bis(4-hydroxyphenyl)dimethyl silane (epoxy equivalent is 278), 100 parts by weight of 2-methacryloyloxyethylbutanedioic acid, 0.3 parts by weight of benzyltriethylammonium chloride, 0.1 parts by weight of 2,6-di-t-butyl-p-cresol and 200 parts by weight of propylene glycol monomethyl ether acetate were continuously added in a 500 ml four neck flask. The feeding speed was controlled at 25 parts by weight per minute, and the temperature of the reaction is maintained at 100° C. to 110° C. After 15 hours, a light yellow mixture having a solid component concentration of 50 wt % could be obtained. Then, the light yellow mixture was subjected to steps, such as extract, flitting and drying, thereby obtain a glycol compound having a polymeric unsaturated group (a-1-6) of Producing Example 6 having a solid component concentration of 99.9 wt %.

### Producing First Alkali-Soluble Resin (A-1)

The first alkali-soluble (A-1) of Synthesis Examples 1 to 10 were according to Table 1 as follows.

### Synthesis Example 1

1.0 mole of the glycol compound having a polymeric unsaturated group made by the aforementioned Producing Example 1, 0.1 moles of 4,4′-hexafluoro isopropylidene diphthalic dianhydride (a-2-1-a), 0.2 moles of pyromellitic dianhydride, 0.4 moles of maleic acid, 1.0 mole of tetrahydrophthalic anhydride, 1.9 g of benzyltriethylammonium chloride, 0.6 g of 2,6-di-tert-butyl-p-cresol and 750 g of propylene glycol monomethyl ether acetate were added into a 500 ml four neck flask at the same time to form a reaction solution. The term “added at the same time” means a tetracarboxylic acid or a dianhydride compound thereof (a-2) and a dicarboxylic acid or an anhydride compound thereof (a-3) were added at the same reaction time. Then, the reaction solution was heated to 110° C., and the reaction was performed for 2 hours, thereby obtaining a first alkali-soluble resin (A-1-1) of Synthesis Example 1. An acid value of the resin (A-1-1) was 129 mgKOH/g and a number average molecule weight was 2368.

### Synthesis Example 2

1.0 mole of the glycol compound having a polymeric unsaturated group made by the aforementioned Producing Example 2 (a-1-2), 2.0 g of benzyltriethylammonium chloride, 0.7 g of 2,6-di-tert-butyl-p-cresol and 700 g of propylene glycol monomethyl ether acetate were added into a 500 ml four neck flask to form a reaction solution. Then, 0.2 moles of 1,4-difluoropyromellitic dianhydride (a-2-1-b) and 0.2 moles of benzophenone tetracarboxylic dianhydride (a-2-2-b) were added, and the reaction was performed at 90° C. for 2 hours. And then, 1.2 moles of tetrahydrophthalic anhydride (a-3-2-b) was added, and the reaction was performed at 90° C. for 4 hours. The term “added respectively” means a tetracarboxylic acid or a dianhydride compound thereof (a-2) and a dicarboxylic acid or an anhydride compound thereof (a-3) were added at the different time. That is to say a tetracarboxylic acid or a dianhydride compound thereof (a-2) was added first, and then a dicarboxylic acid or an anhydride compound thereof (a-3) was added. By the aforementioned processes, a first alkali-soluble resin (A-1-2) of Synthesis Example 2 was obtained, and an acid value of the resin (A-1-2) was 125 mgKOH/g and a number average molecule weight was 3388.

### Synthesis Examples 3, 5, 7 and 9

Synthesis Examples 3, 5, 7 and 9 were practiced with the same method as in Synthesis Example 1 by using various kinds or amounts of the components for the first alkali-soluble resin. The formulations and detection results thereof were listed in Table 1 rather than focusing or mentioning them in details.

### Synthesis Examples 4, 6, 8 and 10

Synthesis Examples 4, 6, 8 and 10 were practiced with the same method as in Synthesis Example 2 by using various kinds or amounts of the components for the first alkali-soluble resin. The formulations and detection results thereof were listed in Table 1 rather than focusing or mentioning them in details.

### Producing Second Alkali-Soluble Resin (A-2)

The second alkali-soluble (A-2) of Synthesis Examples 11 to 13 were according to Table 2 as follows.

### Synthesis Example 11

1.0 mole of the glycol compound having a polymeric unsaturated group made by the aforementioned Producing Example 1 (a-1-1), 1.9 g of benzyltriethylammonium chloride and 0.6 g of 2,6-di-tert-butyl-p-cresol were dissolved in 700 g of propylene glycol monomethyl ether acetate, and 0.3 moles of biphenyl tetracarboxylic acid (a-2-2-a) and 1.4 moles of maleic acid (a-3-2-a) were added at the same time. Then, the solution was heated to 110° C., and the reaction was performed for 2 hours, thereby obtaining a second alkali-soluble resin (A-2-1) of Synthesis Example 11. An acid value of the resin (A-2-1) was 125 mgKOH/g and a number average molecule weight was 2455.

### Synthesis Examples 12 and 13

Synthesis Examples 12 and 13 were practiced with the same method as in Synthesis Example 11 by using various kinds or amounts of the components for the second alkali-soluble resin. The formulations and detection results thereof were listed in Table 2 rather than focusing or mentioning them in details. Noteworthily, the term “added at the same time” means a tetracarboxylic acid or a dianhydride compound thereof (a-2) and a dicarboxylic acid or an anhydride compound thereof (a-3) were added at the same reaction time; and the term “added respectively” means a tetracarboxylic acid or a dianhydride compound thereof (a-2) and a dicarboxylic acid or an anhydride compound thereof (a-3) were added at the different time. That is to say a tetracarboxylic acid or a dianhydride compound thereof (a-2) was added first, and then a dicarboxylic acid or an anhydride compound thereof (a-3) was added.

### Other Alkali-Soluble Resin (A-3)

The other alkali-soluble (A-3) of Synthesis Examples 14 to 16 were according to Table 3 as follows.

### Synthesis Example 3

A nitrogen inlet, a stirrer, a heater, a condenser and a temperature degree were equipped on a 1000 ml four neck flask. After nitrogen was introduced, 30 parts by weight of 2-hydroxyethyl methacrylate (HEMA), 10 parts by weight of benzyl methacrylate (BzMA), 60 parts by weight of CF9BuMA, 3 parts by weight of 2,2′-azobis-2-methyl butyronitrile (AMBN) and 300 parts by weight of diethylene glycol dimethyl ether (Diglyme) were added. Then, the aforementioned mixture was stirred smoothly and the solution was heated to 80° C. Next, polycondensation was performed at 80° C. for 6 hours. And then, the solvent was evaporated, thereby obtaining an other alkali-soluble resin (A-3-1) of Synthesis Example 14.

### Synthesis Examples 15 and 16

Synthesis Examples 15 and 16 were practiced with the same method as in Synthesis Example 14 by using various kinds or amounts of the components for the other alkali-soluble resin. The formulations and detection results thereof were listed in Table 3 rather than focusing or mentioning them in details.

### Producing Oxetane Compound Having a Silicon Atom (F)

### Synthesis Example 17

27.84 g (0.1 moles) of 3-[(3-ethyloxetane-3-yl)methoxy]propyl trimethoxy silane and 0.54 g (30.0 mmoles) of water were added into 80 g of diacetone alcohol (DAA). After stirring at room temperature for a period time, the solution was heated to 60° C., and the solution was stirred for 2 hours. Then, the solution was heated to 160° C. to let DAA and methanol to be azeotropic, and the reaction was performed for 6 hours, thereby the oxetane compound having a silicon atom (F-1-1) diluted by DAA with 20 wt % of solid content is obtained. The oxetane compound having a silicon atom (F-1-1) of Synthesis Example 17 has a structure of Formula (VIII-1):

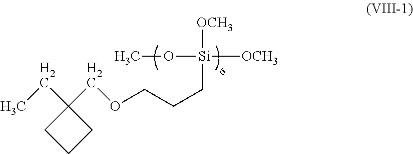

### Synthesis Example 18

22.64 g (0.1 moles) of (3-ethyloxetane-3-yl)methoxy trimethoxy silane and 0.54 g (30.0 mmoles) of water were added into 80 g of DAA. After stirring at room temperature for a period time, the solution was heated to 60° C., and the solution was stirred for 2 hours. Then, the solution was heated to 160° C. to let DAA and methanol to be azeotropic, and the reaction was performed for 6 hours, thereby the oxetane compound having a silicon atom (F-1-2) diluted by DAA with 20 wt % of solid content is obtained. The oxetane compound having a silicon atom (F-1-2) of Synthesis Example 18 has a structure of Formula (VIII-2):

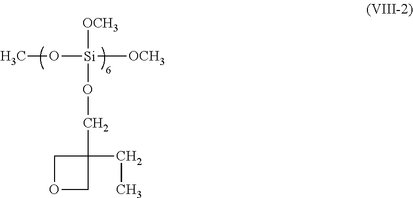

### Synthesis Example 19

89.41 g (0.1 moles) of a compound having a structure of Formula (VIII-3) (t is 7 or 8) and 209.9 g (1.8 mole) of (3-ethyloxetane-3-yl)methanol were added into 400 g of DAA. After stirring at room temperature for a period time, the solution was heated to 60° C., and the solution was stirred for 2 hours. Then, the solution was heated to 160° C. to let DAA and methanol to be azeotropic, and the reaction was performed for 6 hours, thereby the oxetane compound having a silicon atom (F-2-1) diluted by DAA with 20 wt % of solid content is obtained. The oxetane compound having a silicon atom (F-2-1) of Synthesis Example 19 has a structure of Formula (VIII-4), and t is 7 or 8:

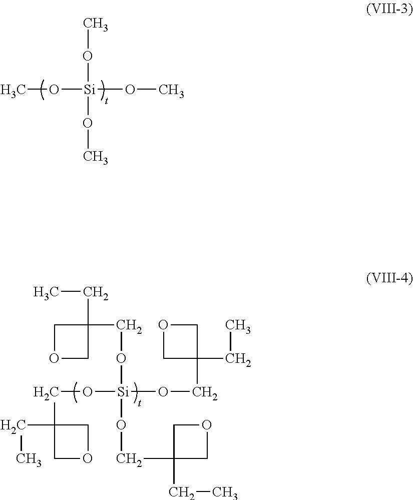

### Synthesis Example 20

95.01 g (0.1 moles) of a compound having a structure of Formula (VIII-5) (u is 7 or 8) and 183.8 g (1.8 mole) of (3-methyloxetane-3-yl)methanol were added into 400 g of DAA. After stirring at room temperature for a period time, the solution was heated to 60° C., and the solution was stirred for 2 hours. Then, the solution was heated to 160° C. to let DAA and methanol to be azeotropic, and the reaction was performed for 6 hours, thereby the oxetane compound having a silicon atom (F-2-2) diluted by DAA with 20 wt % of solid content is obtained. The oxetane compound having a silicon atom (F-2-2) of Synthesis Example 20 has a structure of Formula (VIII-6), and u is 7 or 8:

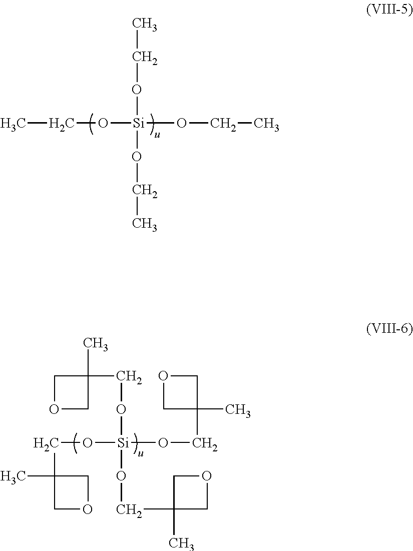

### Producing Photosensitive Resin Composition

The photosensitive resin compositions of Examples 1 to 10 and Comparative Examples 1 to 6 were according to Tables 3 and 4 as follows.

### Example 1

100 parts by weight of the aforementioned first alkali-soluble resin (A-1-1), 15 parts by weight of an ester compound of pentaerythritol triacrylate and o-phthalic acid (B-1-1), 5 parts by weight of trihydroxymethyl triacrylate (B-2-1), 5 parts by weight of 1-[9-ethyl-6-(2-methylbenzoyl)-9H-carbazol-3-yl]-ethanone 1-(O-acetyloxime) (C−1), 60 parts by weight of C.I.Pigment BK7 (E−1) and 1 part by weight of the aforementioned oxetane compound having a silicon atom (F-1-1) were added into 1000 parts by weight of propylene glycol methyl monoether acetate, and the solution was uniformly mixed by a shaking type stirrer, thereby obtaining the photosensitive resin composition of Example 1. The resulted photosensitive resin composition was evaluated according to the following evaluation method, and the result thereof was listed as Table 4. The evaluation methods of the development resistance and the surface resistance were described as follows.

### Examples 2 to 10 and Comparative Examples 1 to 6

Examples 2 to 10 and Comparative Examples 1 to 6 were practiced with the same method as in Example 1 by using various kinds or amounts of the compositions for the photosensitive resin composition. The formulations and detection results thereof were listed in Tables 4 and 5 rather than focusing or mentioning them in details.

### Producing Black Matrix

In coater (bought from Shin Kuang Impoter, and the trade name is MS-A150), the aforementioned photosensitive resin composition was respectively spin-coated on a prime glass substrate of 100 mm*100 mm in size. Next, the glass was dried under 60 Pa for 15 seconds to form a coated film. Then, the substrate which has been coated the coated film was disposed in an oven for pre-baking at 100° C. for 2 minutes to form a pre-baked film with 1.2 μm of film thickness. And then, the pre-baked film was exposed by 100 mJ/cm² of an ultraviolet light (the exposure machine was manufactured by M&R Nano Technology, and the trade name is AG500-4N). After 2 minutes, the exposed substrate was washed by water, and the substrate was post-baked at 230° C. for 60 minutes, thereby forming a black matrix with 1.0 μm of film thickness on the glass substrate.

### Evaluation Methods

### 1. Development Resistance

In coater (bought from Shin Kuang Impoter, and the trade name is MS-A150), the photosensitive resin composition of Examples 1 to 10 and Comparative Examples 1 o 6 were respectively spin-coated on a prime glass substrate of 100 mm*100 mm in size. Next, the glass was dried under 60 Pa for 15 seconds to form a coated film. Then, the substrate which has been coated the coated film was disposed in an oven for pre-baking at 100° C. for 2 minutes to form a pre-baked film. And then, the pre-baked film was exposed by 50 mJ/cm² of an ultraviolet light (the exposure machine was manufactured by M&R Nano Technology, and the trade name is AG500-4N). A film thickness of the pre-baked film (the photosensitive resin layer) was measured before the developing treatment was performed. The exposed pre-coated film was immersed into the developing solution of 0.045% potassium hydroxide at 23° C. for 1 minute, so as to form a glass substrate having a developed coated film. The glass substrate having the developed coated film was washed by water, and disposed in an oven to post-bake at 235° C. for 30 minutes, thereby forming the patterned photosensitive resin layer on the glass substrate. A thickness of the photosensitive resin layer after the developing treatment was measured. A film thickness ratio was calculated according to the following Formula (IX), and an evaluation was made according to the following criterion. When the film thickness ratio was larger, the photosensitive resin composition has better development resistance:

$$film thickness ratio = \frac{film thickness after developing treatment}{film thickness before developing treatment} \times 100 \% \qquad ( IX )$$

⊚: 88%≦film thickness ratio;
◯: 85%≦film thickness ratio<88%;
Δ: 80%≦film thickness ratio<85%;
x: film thickness ratio<80%.

### 2. Surface Resistance

The aforementioned black matrix with 1.0 μm of film thickness made by Examples 1 to 10 and Comparative Examples 1 o 6 were measured by a high resistance meter (manufactured by Mitsubishi Chemical Co., Ltd., and the trade name is MCP-HT450). The resistance meter detected any three detecting points to measure surface resistance, and an averaged value (Ωₛ) was calculated. The evaluation was made according to the following criterion:
⊚: 1.0E+14≦Ωₛ;
◯: 1.0E+12≦Ωₛ<1.0E+14;
Δ: 1.0E+10≦Ωₛ<1.0E+12;
x: Ωₛ<1.0E+10.

According to Tables 4 and 5, when the alkali-soluble resin (A) does not include the first alkali-soluble resin (A-1), the photosensitive resin composition has the defects of poor development resistance and surface resistance. In the first alkali-soluble resin (A-1), when the mole number of the glycol compound having a polymeric unsaturated group (a-1), the mole number of a tetracarboxylic acid having a fluorine atom or a dianhydride compound thereof (a-2-1) and the mole number of a dicarboxylic acid having a fluorine atom or an anhydride compound thereof (a-3-1) satisfy the relationship of [(a-2-1)+(a-3-1)]/(a-1)=0.4 to 1.6, the photosensitive resin composition has better development resistance.

Moreover, when the compound having an ethylenically unsaturated group (B) includes the compound having an acidic group and at least three ethylenically unsaturated groups (B-1), the photosensitive resin composition has better surface resistance.

Furthermore, when the photosensitive resin composition does not include the oxetane compound having a silicon atom (F), the photosensitive resin composition has the defect of poor surface resistance.

Besides, when the photosensitive resin composition further includes the compound having at least two oxirane groups in a molecule (G), the photosensitive resin composition has better surface resistance.

It should be supplemented that, although specific compounds, components, specific reactive conditions, specific processes, specific evaluation methods or specific equipments are employed as exemplary embodiments of the present invention, for illustrating the photosensitive resin composition for the black matrix and the application thereof of the present invention. However, as is understood by a person skilled in the art instead of limiting to the aforementioned examples, the photosensitive resin composition for the black matrix and the application thereof of the present invention also can be manufactured by using other compounds, components, reactive conditions, processes, analysis methods and equipment without departing from the spirit and scope of the present invention.

As is understood by a person skilled in the art, the foregoing preferred embodiments of the present invention are illustrated of the present invention rather than limiting of the present invention. In view of the foregoing, it is intended to cover various modifications and similar arrangements included within the spirit and scope of the appended claims. Therefore, the scope of which should be accorded the broadest interpretation so as to encompass all such modifications and similar structure.

TABLE 1

| | | Polymerized Composition (mole) | | | | | | | | | | | | | | | | |
|---|---|---|---|---|---|---|---|---|---|---|---|---|---|---|---|---|---|---|
| | | | | | | | | Tetracarboxylic Acid or Dianhydride | | | | | | | Dicarboxylic Acid or | | | |
| | | | | | | | | Compound Thereof | | | | | | | Anhydride Compound Thereof | | | |
| | | | | | | | | (a-2) | | | | | | | (a-3) | | | |
| | | | | | | | | Tetracarboxylic Acid | | | | Other | | | Dicarboxylic Acid | | | |
| | | Glycol Compound Having | | | | | | Having a Fluorine Atom or | | | | Tetracarboxylic Acid or | | | Having a Fluorine Atom or | | | |
| | | a Polymeric Unsaturated Group | | | | | | Dianhydride Compound Thereof | | | | Dianhydride Compound Thereof | | | Anhydride Compound Thereof | | | |
| | | (a-1) | | | | | | (a-2-1) | | | | (a-2-2) | | | (a-3-1) | | | |
| Compound | | a-1-1 | a-1-2 | a-1-3 | a-1-4 | a-1-5 | a-1-6 | a-2-1-a | a-2-1-b | a-2-1-c | a-2-1-d | a-2-2-a | a-2-2-b | a-2-2-c | a-3-1-a | a-3-1-b | a-3-1-c | a-3-1-d |
| Synthesis | A-1-1 | 1.0 | | | | | | 0.1 | | | | | | 0.2 | | | | |
| Example 1 | | | | | | | | | | | | | | | | | | |
| Synthesis | A-1-2 | | 1.0 | | | | | | 0.2 | | | | 0.2 | | | | | |
| Example 2 | | | | | | | | | | | | | | | | | | |
| Synthesis | A-1-3 | | | 1.0 | | | | | | 0.1 | 0.2 | 0.3 | | | | | | |
| Example 3 | | | | | | | | | | | | | | | | | | |
| Synthesis | A-1-4 | | | | 1.0 | | | | | | 0.6 | | | | | | | |
| Example 4 | | | | | | | | | | | | | | | | | | |
| Synthesis | A-1-5 | | | | | 1.0 | | | | | | 0.4 | | | 1.2 | | | |
| Example 5 | | | | | | | | | | | | | | | | | | |
| Synthesis | A-1-6 | | | | | | 1.0 | | | | | | 0.1 | | | 1.6 | | |
| Example 6 | | | | | | | | | | | | | | | | | | |
| Synthesis | A-1-7 | 1.0 | | | | | | | | | | | | 0.1 | 1.2 | | 0.6 | |
| Example 7 | | | | | | | | | | | | | | | | | | |
| Synthesis | A-1-8 | | | 1.0 | | | | | | | | | | | | | | 1.9 |
| Example 8 | | | | | | | | | | | | | | | | | | |
| Synthesis | A-1-9 | 0.5 | | 0.3 | 0.2 | | | 0.2 | | | | 0.5 | | | | 0.6 | | |
| Example 9 | | | | | | | | | | | | | | | | | | |
| Synthesis | A-1-10 | | 0.5 | 0.5 | | | | | | | 0.3 | | 0.5 | | | | 0.2 | |
| Example 10 | | | | | | | | | | | | | | | | | | |

| | | Polymerized | | | | | | | | | | | | |
|---|---|---|---|---|---|---|---|---|---|---|---|---|---|---|
| | | Composition | | | | | | | | | | | | |
| | | (mole) | | | | | | | | | | | | |
| | | Dicarboxylic | | | | | | | | | | | | |
| | | Acid or Anhydride | | | | | | | | | | | | |
| | | Compound Thereof | | | | | | | | | | | | |
| | | (a-3) | | | | | | | | | | | | |
| | | Other Dicarboxylic | | | | | | | | | | | | |
| | | Acid or Anhydride | | | | | | | | | | | | |
| | | Compound Thereof | | Method | | | Solvent | | [(a-2-1) + | Reacting | Reacting | | | |
| | | (a-3-2) | | of Adding | Cat. | Inhibitor | (g) | | (a-3-1)]/ | Temp. | Time | | Acid | |
| Compound | | a-3-2-a | a-3-2-b | Monomer | (g) | (g) | PGMEA | EEP | (a-1) | (° C.) | (hour) | | Value | Mn |
| Synthesis | A-1-1 | 0.4 | 1.0 | added at | 1.9 | 0.6 | 750 | | 0.1 | 110 | 2 | | 129 | 2368 |
| Example 1 | | | | the same | | | | | | | | | | |
| | | | | time | | | | | | | | | | |
| Synthesis | A-1-2 | | 1.2 | added | 2.0 | 0.7 | 700 | | 0.2 | 90 | 2 | 4 | 125 | 3388 |
| Example 2 | | | | respec- | | | | | | | | | | |
| | | | | tively | | | | | | | | | | |
| Synthesis | A-1-3 | | 0.8 | added at | 2.9 | 1.0 | 1000 | 100 | 0.3 | 115 | 1.5 | | 87 | 4965 |
| Example 3 | | | | the same | | | | | | | | | | |
| | | | | time | | | | | | | | | | |
| Synthesis | A-1-4 | 0.8 | | added | 1.1 | 0.4 | | 650 | 0.6 | 95 | 1.5 | 4 | 139 | 5201 |
| Example 4 | | | | respec- | | | | | | | | | | |
| | | | | tively | | | | | | | | | | |
| Synthesis | A-1-5 | | | added at | 1.3 | 0.4 | 650 | | 1.2 | 110 | 2 | | 144 | 3665 |
| Example 5 | | | | the same | | | | | | | | | | |
| | | | | time | | | | | | | | | | |
| Synthesis | A-1-6 | | 0.2 | added | 1.1 | 0.4 | 600 | | 1.6 | 90 | 2 | 3.5 | 159 | 1885 |
| Example 6 | | | | respec- | | | | | | | | | | |
| | | | | tively | | | | | | | | | | |
| Synthesis | A-1-7 | | | added at | 1.9 | 0.6 | 800 | | 1.8 | 115 | 1.5 | | 113 | 1732 |
| Example 7 | | | | the same | | | | | | | | | | |
| | | | | time | | | | | | | | | | |
| Synthesis | A-1-8 | | 0.1 | added | 2.9 | 1.0 | 1100 | | 1.9 | 95 | 2 | 3.5 | 87 | 1250 |
| Example 8 | | | | respec- | | | | | | | | | | |
| | | | | tively | | | | | | | | | | |
| Synthesis | A-1-9 | | | added at | 2.0 | 0.7 | | 850 | 0.8 | 110 | 2 | | 108 | 6023 |
| Example 9 | | | | the same | | | | | | | | | | |
| | | | | time | | | | | | | | | | |
| Synthesis | A-1-10 | 0.2 | | added | 2.4 | 0.8 | 100 | 900 | 0.5 | 90 | 2 | 4 | 93 | 6802 |

| | |
|---|---|
| Example 10 | respec- |
| | tively |

TABLE 2

| | | Polymerized Composition (mole) | | | | | | | | | | |
|---|---|---|---|---|---|---|---|---|---|---|---|---|
| | | | | | | | | Tetracarboxylic Acid | | | | |
| | | | | | | | | or Dianhydride | | | | |
| | | | | | | | | Compound Thereof (a-2) | | | | |
| | | | | | | | | Tetracarboxylic Acid | | | | |
| | | Glycol Compound Having | | | | | | Having a Fluorine Atom or | | | | |
| | | a Polymeric Unsaturated Group | | | | | | Dianhydride Compound Thereof | | | | |
| | | (a-1) | | | | | | (a-2-1) | | | | |
| Compound | | a-1-1 | a-1-2 | a-1-3 | a-1-4 | a-1-5 | a-1-6 | a-2-1-a | a-2-1-b | | a-2-1-c | a-2-1-d |
| Synthesis | A-2-1 | 1.0 | | | | | | | | | | |
| Example 11 | | | | | | | | | | | | |
| Synthesis | A-2-2 | | | 1.0 | | | | | | | | |
| Example 12 | | | | | | | | | | | | |
| Synthesis | A-2-3 | | | | | | | | | | | |
| Example 13 | | | 1.0 | | | | | | | | | |
| | | Polymerized Composition (mole) | | | | | | | | | | |
| | | Tetracarboxylic Acid | | | | | | | | | | |
| | | or Dianhydride | | | Dicarboxylic Acid or Anhydride | | | | | | | |
| | | Compound Thereof | | | Compound Thereof | | | | | | | |
| | | (a-2) | | | (a-3) | | | | | | | |
| | | Other Tetracarboxylic | | | Dicarboxylic Acid | | | | Other Dicarboxylic | | | |
| | | Acid or Dianhydride | | | Having a Fluorine Atom or | | | | Acid or Anhydride | | | |
| | | Compound Thereof | | | Anhydride Compound Thereof | | | | Compound Thereof | | | Method |
| | | (a-2-2) | | | (a-3-1) | | | | (a-3-2) | | | of Adding |
| Compound | | a-2-2-a | a-2-2-b | a-2-2-c | a-3-1-a | a-3-1-b | a-3-1-c | a-3-1-d | a-3-2-a | | a-3-2-b | Monomer |
| Synthesis | A-2-1 | 0.3 | | | | | | | 1.4 | | | added at |
| Example 11 | | | | | | | | | | | | the same |
| | | | | | | | | | | | | time |
| Synthesis | A-2-2 | | 0.6 | | | | | | | | 0.8 | added |
| Example 12 | | | | | | | | | | | | respec- |
| | | | | | | | | | | | | tively |
| Synthesis | A-2-3 | | | 0.5 | | | | | 1.0 | | | added |
| Example 13 | | | | | | | | | | | | respec- |
| | | | | | | | | | | | | tively |
| | | | | Solvent | | | | Reacting | Reacting | | | |
| | | Cat. | Inhibitor | (g) | | (a-2)/ | (a-3)/ | Temp. | Time | | Acid | |
| Compound | | (g) | (g) | PGMEA | EEP | (a-1) | (a-1) | (° C.) | (hour) | | Value | Mn |
| Synthesis | A-2-1 | 1.9 | 0.6 | 700 | | 0.0 | 0.0 | 110 | 2 | | 125 | 2455 |
| Example 11 | | | | | | | | | | | | |
| Synthesis | A-2-2 | 2.9 | 0.0 | 950 | | 0.0 | 0.0 | 90 | 2 | 4 | 92 | 5130 |
| Example 12 | | | | | | | | | | | | |
| Synthesis | A-2-3 | 2.5 | 0.0 | 900 | | 0.0 | 0.0 | 90 | 2 | 4 | 102 | 4280 |

Example 13

a-1-1 glycol compound having a polymeric unsaturated group (a-1-1) of Producing Example 1
a-1-2 glycol compound having a polymeric unsaturated group (a-1-2) of Producing Example 2
a-1-3 glycol compound having a polymeric unsaturated group (a-1-3) of Producing Example 3
a-1-4 glycol compound having a polymeric unsaturated group (a-1-4) of Producing Example 4
a-1-5 glycol compound having a polymeric unsaturated group (a-1-5) of Producing Example 5
a-1-6 glycol compound having a polymeric unsaturated group (a-1-6) of Producing Example 6
a-2-1-a 4,4′-hexafluoro isopropylidene diphthalic dianhydride
a-2-1-b 1,4-difluoropyromellitic dianhydride
a-2-1-c 1,4-difluoropyromellitic dianhydride
a-2-1-d 1,4-bis(3,4-dicarboxytrifluorophenoxy)tetrafluoro benzenedianhydride
a-2-2-a Biphenyl tetracarboxylic acid
a-2-2-b Benzophenone tetracarboxylic dianhydride
a-2-2-c Pyromellitic dianhydride
a-3-1-a 3-fluorophthalic anhydride
a-3-1-b 3,6-difluorophthalic anhydride
a-3-1-c 4-fluorophthalic anhydride
a-3-1-d tetrafluoro succinic anhydride
a-3-2-a Maleic acid
a-3-2-b Tetrahydro phthalic anhydride
PGMEA propylene glycol monomethyl ether acetate
EEP ethyl 3-ethoxypropanoate
Cat. benzyltriethylammonium chloride
Inhibitor 2,6-di-tert-butyl-p-cresol

TABLE 3

| | | Composition (Part by Weight) | | | | | | | |
|---|---|---|---|---|---|---|---|---|---|
| | | | | | | | | Monomer Having a | |
| | | Monomer | | | | | | Fluorine Atom | |
| Compound | | MAA | AA | GMA | HEMA | BzMA | IBOMA | CF9BuMA | CF9PEMA |
| Synthesis | A-3-1 | | 15 | | 15 | 10 | | 60 | |
| Example 14 | | | | | | | | | |
| Synthesis | A-3-2 | 20 | | | 10 | | 10 | | 60 |
| Example 15 | | | | | | | | | |
| Synthesis | A-3-3 | 10 | 20 | 10 | | 20 | 40 | | |
| Example 16 | | | | | | | | | |

| | | Composition (Part by Weight) | | | | | Poly- |
|---|---|---|---|---|---|---|---|
| | | Solvent | | Initiator | | Reacting | condensation |
| Compound | | Diglyme | PGMEA | AMBN | ADVN | Temp. (°C.) | time (hour) |
| Synthesis | A-3-1 | 300 | | 3.0 | | 80 | 6 |
| Example 14 | | | | | | | |
| Synthesis | A-3-2 | | 300 | 3.0 | | 80 | 6 |
| Example 15 | | | | | | | |
| Synthesis | A-3-3 | 300 | | | 2.0 | 80 | 6 |
| Example 16 | | | | | | | |

| | |
|---|---|
| MAA | methacrylic acid |
| AA | acrylic acid |
| GMA | glycidyl methacylate |
| HEMA | (2-hydroxyethyl)methacrylate |
| BzMA | benzyl methacrylate |
| IBOMA | Isobornyl methacrylate |
| CF9BuMA | CH₂═C(CH₃)COOCH₂CH₂CH₂CH₂OC₉F₁₇ |
| CF9PEMA | CH₂═C(CH₃)COOCH₂CH₂OCOC₆H₄OC₉F₁₇ |
| Diglyme | diethylene glycol dimethyl ether |
| PGMEA | Propylene glycol monoethyl ether acetate |
| AMBN | 2,2′-azobis-2-methyl butyronitrile |
| ADVN | 2,2′-azobis(2,4-dimethylvaleronitrile) |

TABLE 4

| | | | Example | | | | | | | | | |
|---|---|---|---|---|---|---|---|---|---|---|---|---|
| Composition (Part by Weight) | | | 1 | 2 | 3 | 4 | 5 | 6 | 7 | 8 | 9 | 10 |
| Alkali-soluble | A 1 | A-1-1 | 100 | | | | | | | | | |
| Resin | | A-1-2 | | 90 | | | | | | | | |
| (A) | | A-1-3 | | | 80 | | | | | | | |
| | | A-1-4 | | | | 75 | | | | | | |
| | | A-1-5 | | | | | 70 | | | | | |
| | | A-1-6 | | | | | | 45 | | | | |
| | | A-1-7 | | | | | | | 30 | | | |
| | | A-1-8 | | | | | | | | 25 | | |
| | | A-1-9 | | | | | | | | | 15 | |
| | | A-1-10 | | | | | | | | | | 10 |
| | A-2 | A-2-1 | | 10 | | | | 40 | | | 85 | |
| | | A-2-2 | | | 20 | | 30 | | 50 | 75 | | |
| | | A-2-3 | | | | 25 | | | | | | 60 |
| | A-3 | A-3-1 | | | | | | 15 | | | | |
| | | A-3-2 | | | | | | | 20 | | | |
| | | A-3-3 | | | | | | | | | | 30 |
| Compound | B-1 | B-1-1 | 15 | | | | | | | | | |
| Having an | | B-1-2 | | 60 | | | | | | | 150 | |
| Ethylenically | | B-1-3 | | | | | | 90 | | | | |
| Unsaturated | B 2 | B-2-1 | 5 | | | 35 | 60 | | 100 | | | 135 |
| Group | | B-2-2 | | | 30 | | | | | 120 | 50 | |
| (B) | | | | | | | | | | | | |
| Photo-initiator | C-1 | | 5 | | | 15 | | 30 | | 40 | | 35 |
| (C) | C-2 | | | 20 | | | 10 | | | | 45 | |
| | C-3 | | | | 30 | 5 | | | 35 | | | 20 |
| Solvent | D-1 | | 1000 | | 1500 | | 3000 | 1300 | | 4600 | | 2000 |
| (D) | D-2 | | | 2700 | | 2200 | | 600 | 3800 | | 5000 | 1300 |
| Black Pigment | E-1 | | 60 | | 150 | | 240 | | 300 | | 550 | |
| (E) | E-2 | | | 85 | | 200 | | 320 | 100 | 470 | | 600 |
| Oxetane | F 1 | F-1-1 | 1 | | | | 5 | | | 1 | | |
| Compound | | F-1-2 | | 1.5 | | 4 | | 6.5 | | | 9 | |
| Having a | F 2 | F-2-1 | | | 3 | | | | | 1.5 | | |
| Silicon Atom | | F-2-2 | | | | | | | 8.5 | | | 10 |
| (F) | | | | | | | | | | | | |

| | | | | | | | | | | | |
|---|---|---|---|---|---|---|---|---|---|---|---|
| Compound | G-1 | | | 30 | | | | | | | |
| Having at | G-2 | | | | | 60 | | | | | |
| Least Two | G-3 | | | | | | 120 | | | | |
| Oxirane | | | | | | | | | | | |
| Groups in a | | | | | | | | | | | |
| Molecule | | | | | | | | | | | |
| (G) | | | | | | | | | | | |
| Evaluated | Development | ◯ | ◯ | ◯ | ⊚ | ⊚ | ⊚ | ◯ | ◯ | ⊚ | ⊚ |
| Result | Resistant | | | | | | | | | | |
| | Surface | ⊚ | ⊚ | ⊚ | ◯ | ⊚ | ⊚ | ◯ | ◯ | ⊚ | ◯ |
| | Resistance | | | | | | | | | | |

B-1-1 ester compound of pentaerythritol triacrylate and o-phthalic acid
B-1-2 ester compound of dipentaerythritol pentamethylacrylate and succinic acid
B-1-3 ester compound of dipentaerythritol pentamethylacrylate and o-phthalic acid
B-2-1 trimethylolpropane triacrylate
B-2-2 dipentaerythritol hexacrylate
C-1 1[9-ethyl-6-(2-methylbenzoyl)-9H-carbazol-3-yl]-ethanone 1-(O-acetyloxime) (made by Ciba Specialty Chemicals Co., Ltd., and the trade name is OXE-02)
C-2 1[4-(phenylthio)phenyl]-octane-1,2-dione-2-(O-benzoyloxime) (made by Ciba Specialty Chemicals Co., Ltd., and the trade name is OXE-01)
C-3 2-methyl-1-(4-methylthio)phenyl-2-morpholinyl-1-propanone (made by Ciba Specialty Chemicals Co., Ltd., and the trade name is IRGACURE 907)
D-1 propylene glycol monomethyl ether acetate
D-2 ethyl 3-ethoxypropanoate
E-1 C.I. Pigment BK7
E-2 MA100 (made by Mitsubishi Chemical Co., Ltd.)
F-1-1 oxetane compiund having a silicon atom of Synthesis Example 17
F-1-2 oxetane compiund having a silicon atom of Synthesis Example 18
F-2-1 oxetane compiund having a silicon atom of Synthesis Example 19
F-2-2 oxetane compiund having a silicon atom of Synthesis Example 20
G-1 JER157S70 (made by Mitsubishi Chemical Co., Ltd.)
G-2 Denacol EX-611 (made by Nagase Chemtex Co., Ltd.)
G-3 YH-300 (made by Nippon Steel Chemical Co., Ltd.)

TABLE 5

| | | | Comparative Example | | | | | |
|---|---|---|---|---|---|---|---|---|
| Composition (Part by Weight) | | | 1 | 2 | 3 | 4 | 5 | 6 |
| Alkali-soluble | A 1 | A-1-1 | | | | | 100 | |
| Resin (A) | | A-1-2 | | | | | | |
| | | A-1-3 | | | | | | |
| | | A-1-4 | | | | | | |
| | | A-1-5 | | | | | | |
| | | A-1-6 | | | | | | |
| | | A-1-7 | | | | | | |
| | | A-1-8 | | | | | | |
| | | A-1-9 | | | | | | |
| | | A-1-10 | | | | | | |
| | A-2 | A-2-1 | 100 | | | | | 100 |
| | | A-2-2 | | 100 | | | | |
| | | A-2-3 | | | | | | |
| | A-3 | A-3-1 | | | 100 | | | |
| | | A-3-2 | | | | | | |
| | | A-3-3 | | | | 100 | | |
| Compound | B-1 | B-1-1 | | | | | | |
| Having an | | B-1-2 | | | | | | |
| Ethylenically | | B-1-3 | | | | | | |
| Unsaturated | B 2 | B-2-1 | 50 | | 50 | | 100 | |
| Group | | B-2-2 | | 50 | | 50 | | 100 |
| (B) | | | | | | | | |
| Photo-initiator | C-1 | | 25 | | | 25 | | |
| (C) | C-2 | | | 25 | | | 30 | |
| | C-3 | | | | 25 | | | 30 |
| Solvent | D-1 | | 2500 | 2500 | | | 2500 | 2500 |
| (D) | D-2 | | | | 2500 | 2500 | | |
| Black Pigment | E-1 | | 200 | | 250 | 250 | 250 | |
| (E) | E-2 | | | 200 | | | | 250 |
| Oxetane | F 1 | F-1-1 | 5 | | | | | |
| Compound | | F-1-2 | | 5 | | | | |
| Having a | F 2 | F-2-1 | | | 5 | | | |
| Silicon Atom | | F-2-2 | | | | 5 | | |
| (F) | | | | | | | | |

| | | | | | | | |
|---|---|---|---|---|---|---|---|
| Compound | G-1 | | | | | | |
| Having at | G-2 | | | | | | |
| Least Two | G-3 | | | | | | |
| Oxirane | | | | | | | |
| Groups in a | | | | | | | |
| Molecule | | | | | | | |
| (G) | | | | | | | |
| Evaluated | Development | X | X | X | X | ◯ | X |
| Result | Resistant | | | | | | |
| | Surface | X | X | X | X | X | X |
| | Resistance | | | | | | |

B-1-1 ester compound of pentaerythritol triacrylate and o-phthalic acid
B-1-2 ester compound of dipentaerythritol pentamethylacrylate and succinic acid
B-1-3 ester compound of dipentaerythritol pentamethylacrylate and o-phthalic acid
B-2-1 trimethylolpropane triacrylate
B-2-2 dipentaerythritol hexacrylate
C-1 1-[9-ethyl-6-(2-methylbenzoyl)-9H-carbazol-3-yl]-ethanone 1-(O-acetyloxime) (made by Ciba Specialty Chemicals Co., Ltd., and the trade name is OXE-02)
C-2 1-[4-(phenylthio)phenyl]-octane-1,2-dione-2-(O-benzoyloxime) (made by Ciba Specialty Chemicals Co., Ltd., and the trade name is OXE-01)
C-3 2-methyl-1-(4-methylthio)phenyl-2-morpholinyl-1-propanone (made by Ciba Specialty Chemicals Co., Ltd., and the trade name is IRGACURE 907)
D-1 propylene glycol monomethyl ether acetate
D-2 ethyl 3-ethoxypropanoate
E-1 C.I. Pigment BK7
E-2 MA100 (made by Mitsubishi Chemical Co., Ltd.)
F-1-1 oxetane compiund having a silicon atom of Synthesis Example 17
F-1-2 oxetane compiund having a silicon atom of Synthesis Example 18
F-2-1 oxetane compiund having a silicon atom of Synthesis Example 19
F-2-2 oxetane compiund having a silicon atom of Synthesis Example 20
G-1 JER157S70 (made by Mitsubishi Chemical Co., Ltd.)
G-2 Denacol EX-611 (made by Nagase Chemtex Co., Ltd.)
G-3 YH-300 (made by Nippon Steel Chemical Co., Ltd.)

What is claimed is:

1. A photosensitive resin composition for a black matrix, comprising:
an alkali-soluble resin (A), includes a first alkali-soluble resin (A-1) having a structure of Formula (I): 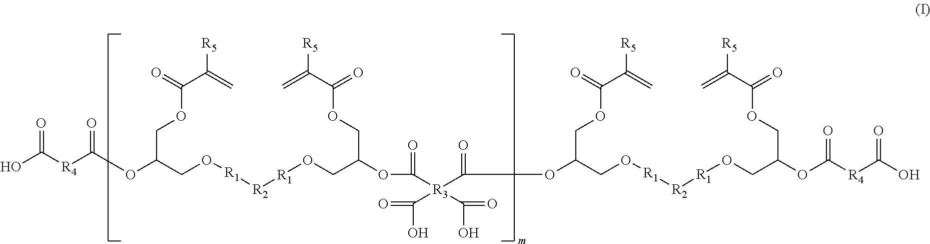
in the Formula (I), R₁ represents a phenylene group or a phenylene having a substituted group, wherein the substituted group is optionally an alkyl group of 1 to 5 carbons, a halogen atom or a phenyl group; R₂ represents —CO—, —SO₂—, —C(CF₃)₂—, —SI(CH₃)₂—, —CH₂—, —C(CH₃)₂—, —O—, 9,9-fluorenylidene or a single bond; R₃ represents a tetravalent carboxylic residual group; R₄ represents a divalent carboxylic residual group, wherein at least one of R₃ and R₄ have a fluorine atom; R₅ represents a hydrogen atom or a methyl group; and m represents an integer of 1 to 20;
a compound having an ethylenically unsaturated group (B);
a photo-initiator (C);
a solvent (D);
a black pigment (E); and
an oxetane compound having a silicon atom (F), and
wherein a weight-average molecule weight of the oxetane compound having a silicon atom (F) is 200 to 4000.

2. The photosensitive resin composition for the black matrix of claim 1, wherein the first alkali-soluble resin (A-1) is obtained by reacting with a first mixture, and the first mixture includes:
a glycol compound having a polymeric unsaturated group (a-1);
a tetracarboxylic acid or a dianhydride compound thereof (a-2); and
a dicarboxylic acid or an anhydride compound thereof (a-3), and
wherein a tetracarboxylic acid or a dianhydride compound thereof (a-2) includes a tetracarboxylic acid having a fluorine atom or a dianhydride compound thereof (a-2-1) and an other tetracarboxylic acid or a dianhydride compound thereof (a-2-2) besides a tetracarboxylic acid having a fluorine atom or a dianhydride compound thereof (a-2-1), a dicarboxylic acid or an anhydride compound thereof (a-3) includes a dicarboxylic acid having a fluorine atom or an anhydride compound thereof (a-3-1) and an other dicarboxylic acid or an anhydride compound thereof (a-3-2) besides a dicarboxylic acid having a fluorine atom or an anhydride compound thereof (a-3-1), and at least one of a tetracarboxylic acid or a dianhydride compound thereof (a-2) and a dicarboxylic acid or an anhydride compound thereof (a-3) have a fluorine atom.

3. The photosensitive resin composition for the black matrix of claim 2, wherein a tetracarboxylic acid having a fluorine atom or a dianhydride compound thereof (a-2-1) is selected from a group consisting of a tetracarboxylic acid having a fluorine atom having a structure of Formula (I-1), a tetracarboxylic dianhydride compound having a fluorine atom having a structure of Formula (I-2) and a combination thereof: 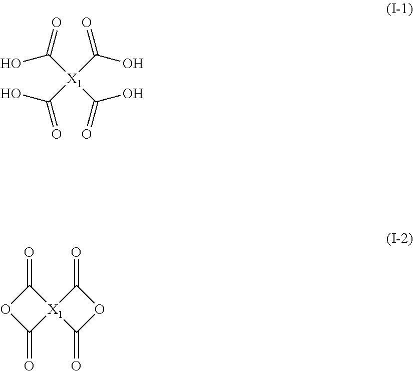
in the Formula (I-1) and (I-2), X₁ represents a group having a structure of Formula (I-3) to (I-8): 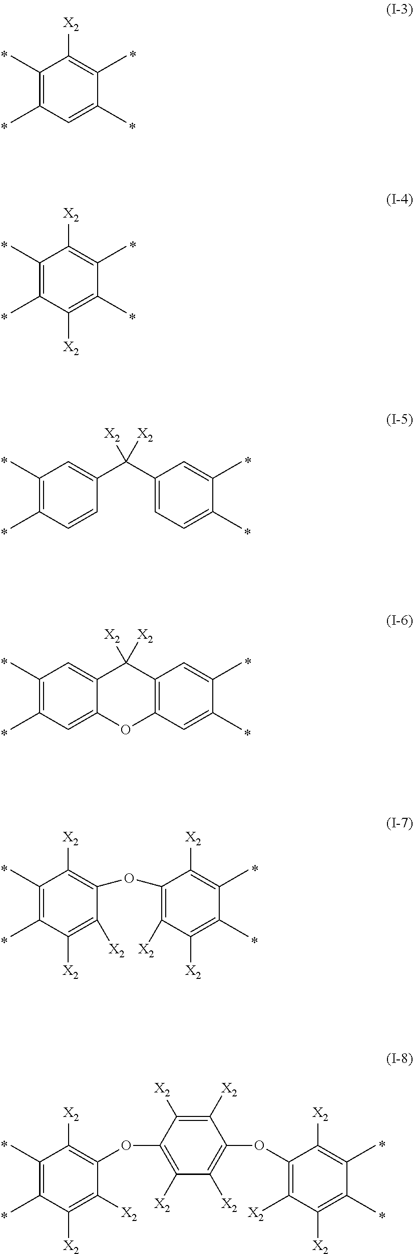
in the Formula (I-3) to (I-8), X₂ respectively represents a fluorine atom or a trifluoromethyl, and “*” represents a position bonding with a carbon atom.

4. The photosensitive resin composition for the black matrix of claim 2, wherein a dicarboxylic acid having a fluorine atom or an anhydride compound thereof (a-3-1) is selected from a group consisting of a dicarboxylic acid having a fluorine atom having a structure of Formula (I-9), a dicarboxylic anhydride compound having a fluorine atom having a structure of Formula (I-10) and a combination thereof: 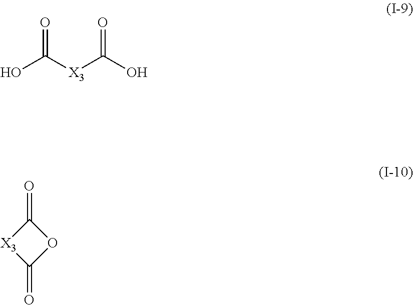
in the Formula (I-9) and (I-10), X₃ represents an organic group having a fluorine atom of 1 to 100 carbons.

5. The photosensitive resin composition for the black matrix of claim 2, wherein a molar ratio {[(a-2-1)+(a-3-1)]/(a-1)} of a total mole number of a tetracarboxylic acid having a fluorine atom or a dianhydride compound thereof (a-2-1) and a dicarboxylic acid having a fluorine atom or an anhydride compound thereof (a-3-1) to a mole number of the glycol compound having a polymeric unsaturated group (a-1) is 0.4 to 1.6.

6. The photosensitive resin composition for the black matrix of claim 1, wherein the oxetane compound having a silicon atom (F) includes a first oxetane compound having a silicon atom (F-1), a second oxetane compound having a silicon atom (F-2) or a combination thereof, and
wherein the first oxetane compound having a silicon atom (F-1) is a compound having a structure of Formula (II) or a condensate of the compound having a structure of Formula (II):
Si(Y₁)ₐ(OY₂)₄₋ₐ (II)
In the Formula (II), Y₁ and Y₂ respectively represent an alkyl group of 1 to 8 carbons, a cycloalkyl group of 6 to 10 carbons, an aromatic of 6 to 10 carbons, an alkyl carbonyl group of 2 to 7 carbons or an organic group having an oxetanyl group, wherein at least one of Y₁ and Y₂ is the organic group having an oxetanyl group, and a represents an integer of 0 to 3;
the second oxetane compound having a silicon atom (F-2) is obtained by subjected a compound having a structure of Formula (III) to a thermal condensation reaction, and then subjected to an ester-interchange reaction with an oxetane compound having a hydroxyl group having a structure of Formula (IV):
Si(Y₃)_{b}(OY₄)_{4-b} (III)
in the Formula (III), Y₃ respectively represents an alkyl group of 1 to 8 carbons, a cycloalkyl group of 6 to 10 carbons or an aromatic group of 6 to 10 carbons; Y₄ respectively represents an alkyl group of 1 to 8 carbons, a cycloalkyl group of 6 to 10 carbons, an aromatic group of 6 to 10 carbons or an alkyl carbonyl group of 2 to 5 carbons, and b represents an integer of 0 to 2; 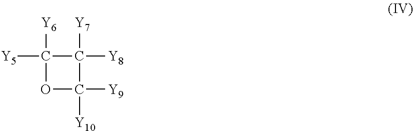
in the Formula (IV), Y₅ to Y₁₀ respectively represents a hydrogen atom, a fluorine atom, an alkyl group of 1 to 4, an alkyl group having a hydroxyl group or a phenyl group, wherein at least one of Y₅ to Y₁₀ represents the alkyl group having a hydroxyl group.

7. The photosensitive resin composition for the black matrix of claim 1, wherein the compound having an ethylenically unsaturated group (B) includes a compound having an acidic group and at least three ethylenically unsaturated groups (B-1).

8. The photosensitive resin composition for the black matrix of claim 1, wherein based on a total amount of the alkali-soluble resin (A) as 100 parts by weight, an amount of the first alkali-soluble resin (A-1) is 10 parts by weight to 100 parts by weight, an amount of the compound having an ethylenically unsaturated group (B) is 20 parts by weight to 200 parts by weight, an amount of the photo-initiator (C) is 5 parts by weight to 55 parts by weight, an amount of the solvent (D) is 1000 parts by weight to 5000 parts by weight, an amount of the black pigment (E) is 60 parts by weight to 600 parts by weight, and an amount of the oxetane compound having a silicon atom (F) is 1 part by weight to 10 parts by weight.

9. The photosensitive resin composition for the black matrix of claim 7, wherein based on the total amount of the alkali-soluble resin (A) is 100 parts by weight, an amount of the compound having an acidic group and at least three ethylenically unsaturated groups (B-1) is 15 parts by weight to 150 parts by weight.

10. The photosensitive resin composition of the black matrix of claim 1, further comprises a compound having at least two oxirane groups in a molecule (G).

11. The photosensitive resin composition of the black matrix of claim 10, wherein based on a total amount of the alkali-soluble resin as 100 parts by weight, an amount of the compound having at least two oxirane groups in a molecule (G) is 30 parts by weight to 120 parts by weight.

12. A black matrix, formed by a photosensitive resin composition for a black matrix of claim 1.

13. A color filter, comprises a black matrix of claim 12.

14. A liquid crystal display device, comprises a color filter of claim 13.
